(19) United States
(12) Patent Application Publication
(10) Pub. No.: US 2009/0046441 A1
(43) Pub. Date: Feb. 19, 2009

(54) WIRING BOARD FOR MOUNTING SEMICONDUCTOR DEVICE, MANUFACTURING METHOD OF THE SAME, AND WIRING BOARD ASSEMBLY

(75) Inventors: Takuo Funaya, Tokyo (JP); Hideya Murai, Tokyo (JP); Shintaro Yamamichi, Tokyo (JP); Katsumi Kikuchi, Tokyo (JP); Hirokazu Honda, Kanagawa (JP); Shinichi Miyazaki, Kanagawa (JP)

Correspondence Address: YOUNG & THOMPSON, 209 Madison Street, Suite 500, ALEXANDRIA, VA, 22314, US

(73) Assignees: Nec Corporation, Tokyo (JP); Nec Electronics Corporation, Kawasaki-shi (JP)

(21) Appl. No.: 12/160,132

(22) PCT Filed: Dec. 20, 2006
(86) PCT No.: PCT/JP2006/325348

§ 371 Date: Jul. 7, 2008

(30) Foreign Application Priority Data
Jan. 6, 2006 (JP) 2006-001921

(51) Int. Cl. H05K 1/11; H05K 1/18

(52) U.S. Cl. 361/783; 174/261

(57) ABSTRACT

A wiring board for mounting semiconductor device, includes at least a dielectric film 1; wirings formed in the dielectric film 1; a plurality of electrode pads provided at front and back surfaces of the dielectric film with their surfaces exposed and at least portions of lateral sides of them buried into the dielectric film; vias connecting the wirings and the electrode pads. At least one via connecting each other the wirings formed in the dielectric film includes second material different from first material forming the vias connecting the wirings and the electrode pads. The wiring board for mounting semiconductor device, is effective for an increase in terminals and finer pitch of terminal intervals due to an improvement in integration, performance or multi-function of semiconductor devices, can mount semiconductor devices especially on both sides of the board at a high density and high accuracy, and furthermore, is excellent in reliability as well.

### TECHNICAL FIELD

The present invention relates to a wiring board for mounting semiconductor device, a manufacturing method of the same, and a wiring board assembly using the wiring board, and in particular, relates to a wiring board for mounting semiconductor device, which can provide a high performance and high reliability wiring board assembly and module, and a manufacturing method of the same, and a wiring board assembly using the wiring board.

### BACKGROUND ART

Recently, as semiconductor devices get higher integrated, higher performance, and larger number of functions, the number of the terminals increases and the pitch between the terminals becomes narrower. As for a wiring board for mounting such semiconductor devices, it is required to mount semiconductor devices at a higher density and higher accuracy, and to be more excellent in reliability than before. Examples of the wiring board for mounting semiconductor devices often used currently include a build-up board which is prepared by forming wiring layers of high density on a printed board as core by using a sequential stacking method and a simultaneously-stacked multilayer wiring board which is formed by simultaneously stacking wiring layers and resin sheets in which vias are formed. Japanese Laid Open Patent Application (JP-P2001-284783A) discloses an example of the build-up board. Japanese Laid Open Patent Application (JP-P2003-347738A) discloses an example of the simultaneously-stacked multilayer wiring board.

FIG. 26 is a cross-sectional view of a build-up board. As shown in FIG. 26, a base core board 103 has a multilayer wiring structure formed in a dielectric layer. Conductor wiring layers 102 provided on the front surface and back surface of the base core board 103 are connected by a through hole 101 that penetrates the dielectric layer of the base core board 103. Interlayer dielectric films 105 are formed on both of the front and back surfaces of the base core board 103. A conductor wiring layer 106 is formed on each interlayer dielectric film 105. A solder resist layer 107 is formed on the interlayer dielectric film 105 to partially cover the conductor wiring layer 106. A via 104 for electrically connecting the above conductor wiring and the below conductor wiring are formed in each interlayer dielectric film 105. When further increase in the number of the layers is necessary, a multilayer wiring structure is formed by repeating the forming process of the interlayer dielectric film 105 and the forming process of the conductor wiring layer 106 one after the other.

On the other hand, FIGS. 27A to 27C are cross-sectional views showing an example of the manufacturing method of a simultaneously-stacked multilayer wiring board in the order of processes. As for the conventional simultaneously-stacked multilayer wiring board, as shown in FIG. 27A, a conductor wiring layer 112 is patterned on a resin sheet 111. In the resin sheet 111, a via 113 connected to the conductor wiring layer 112 is provided. As shown in FIG. 27B, a plurality of such resin sheets 111 are prepared. These are simultaneously stacked to form the simultaneously-stacked multilayer wiring board 114 as shown in FIG. 27C. The simultaneously-stacked multilayer wiring board 114 may be referred to as the board 114.

Such a simultaneously-stacked multilayer wiring board has a problem that the attenuation of fine pitch is difficult since every via portion depends on filled paste by printing. Moreover, in order to provide a thinner board, the resin sheet is required to be thin. In this case, there is a problem that the entire board 114 has undulating shape depending on the arrangement of the vias after the press in the simultaneous stacking.

These conventional build-up board and simultaneously-stacked multilayer wiring board have structures in which a conductor wiring layer is formed on a dielectric film and an electrode pad for mounting a semiconductor device is formed on the dielectric film. Recently, as wiring of such wiring board becomes denser and finer, the forming method of the conductor wiring layers 102, 106 and 112 is changing from a subtractive method in which copper foil is etched to an additive method in which an electrode is provided to pattern a resist and an electrolytic plated layer is deposited and stacked.

However, electrode pads formed by the additive method have defects that their heights greatly vary each other and the top surfaces of the electrode pads are not flat-shaped but convex-shaped. Therefore, it is difficult to mount a semiconductor device having large number of pins with narrower pitch on the electrode pads. In addition, the solder resist layer 107 is often formed on the electrode pads. The great variation in the heights of the electrode pads makes it extremely difficult to achieve precisely the desired thickness of the solder resist layer and the desired diameter of the opening in the solder resist layer. Further more, as the electrode pads become finer, the adhesion area between the electrode pad and the dielectric film is reduced. Therefore, the adhesion force between the electrode pad and the dielectric film is reduced and the problem is caused that the electrode pad is stripped off the dielectric film especially in the semiconductor device mounting process at high temperature in which lead-free solder is used.

In order to solve the various problems mentioned above, the applicant(s) has(have) proposed a method in which a wiring structure is formed on a supporting body composed of a flat metal plate, electrode pads are formed on the supporting body, and a semiconductor device is mounted on the electrode pads. This method is disclosed in Japanese Laid Open Patent Application (JP-P2002-83893A).

However, following the recent remarkable progress in the performance and increase in the number of functions of mobile devices and the like, there is an increasing demand for mounting semiconductor devices on both the front and back surfaces of a wiring board in order to mount the semiconductor devices at a high density. In the case of the conventional wiring board disclosed in Japanese Laid Open Patent Application (JP-P2002-83893A) mentioned above, it is possible to mount semiconductor devices on a single side but it is difficult to mount semiconductor devices on both sides at a high density.

In addition, it is desirable that interlayer dielectric films of a wiring board for mounting semiconductor devices includes an interlayer dielectric film having a low thermal expansion coefficient or low elastic modulus in order to achieving the high reliability of a wiring board assembly. However, when a dielectric film with a different physical property value is applied in the case of the above-mentioned conventional wiring board, there is a problem that deterioration in reliability is caused due to the structure.

Consequently, various methods are disclosed about a wiring board which is formed by stacking dielectrics each having a wiring layer at the surface.

Japanese Laid Open Patent Application (JP-A-Heisei 10-084186) discloses a method to obtain a wiring board, in which wiring layers are formed on both the surfaces of an adhesive dielectric with holes provided at the positions corresponding to a wiring pattern of a wiring layer and buried with conductors and via connections are formed at the same time by transferring a conductive wiring pattern formed on the surface of a releasable supporting plate to each of both the surfaces of the adhesive dielectric by pressing, and then the releasable supporting plate is removed. In this method, stacking is performed by arranging a wiring board between two both side wiring boards each having printed wirings connected by via, by putting a removable supporting plate with a conductive wiring pattern formed on the surface on each of the two both side wiring boards and by applying heat and pressure to the removable supporting boards for a determined time at predetermined temperature and pressure with a vacuum pressing machine.

Japanese Laid Open Patent Application (JP-P2003-60348A) discloses a method to form a printed board, in which a plurality of resin films formed of the same thermoplastic resin and including a resin film with a wiring pattern formed on only the single side are staked and then pressurized and heated to be stuck to each other. In the method, a conductor pattern is formed on only the single side of a resin film. Then, a single-side conductor pattern film with a via hole filled with conductive paste and another single-side conductor pattern film formed by the same method with a conductor pattern including only electrode portions are stacked, and applied with pressure and heat. Thus, a printed board with only the electrode portions exposed at the surface is formed without forming a solder resist layer.

Japanese Laid Open Patent Application (JP-P2003-188536A) discloses a method in which, a laminate made of ceramic material, having a conductor pattern made of copper or the like on the surface and being provided with via holes filled with epoxy resin, metal paste or the like, and a laminate made of organic material, having a conductor pattern made of copper or the like on the surface and being provided with via holes filled with epoxy resin, metal paste or the like, are stuck together through an interlayer dielectric layer including a photosensitive resin sheet obtained by providing photosensitivity to an insulating sheet material containing mainly thermosetting resin such as epoxy in a partially thermoset state. A dielectric film such as solder resist film is formed on the sticking surface to provide flatness.

Japanese Laid Open Patent Application (JP-P2004-228165A) discloses a structure in which a conductor layer of a single-side wiring circuit-provided resin base material having the conductor layer on the single side of a dielectric base material is electrically connected through a conductor such as conductive paste in inner via hole formed in the single-side wiring circuit-provided resin base material to a conductor layer of a motherboard printed board which is made of a flexible resin such as polyimide and provided with conductor layers on both the front and back surface. This enables that a multilayer portion (partial wiring board) for mounting electric device is provided at the desired position on the surface of the motherboard printed wiring hoard while reducing unnecessary multilayer portions.

Japanese Laid Open Patent Application (JP-A-Heisei 5-335747) discloses a ceramic multilayer board provided with a semiconductor element directly connected to the ceramic multilayer board through solder bumps. Wiring electrodes are not provided to at least vias for flip-chip mounting among the vias in the uppermost and lowermost layers of the ceramic multilayer board and only the vias for flip-chip mounting are formed of Cu material not including Al₂O₃. Other vias provided in intermediate layers are formed of composite material including 10 wt % to 20 wt % Al₂O₃ and Cu for the rest. The vias for flip-chip mounting have depressions since Cu contracts greater than glass ceramic as the base material. These vias themselves are takeout electrodes corresponding to the solder bumps. Therefore, the solder bumps are fixed in the depressions and are not likely to be deformed. Consequently, reflow of the solder bumps is improved.

Japanese Laid Open Patent Application (JP-P2005-123332A) discloses a circuit board having a multilayer board and an electronic part. As for the multilayer board, a plurality of conductor patterns are arranged in the form of multiple layers in an insulating board. The conductor patterns are electrically connected to each other through a plurality of interlayer connecting materials respectively filled in a plurality of via holes. The plurality of conductor patterns include a conductor pattern serving as a land provided on the surface of the multilayer board. The electronic part is electrically connected to the land through joining material. The plurality of interlayer connecting materials are electrically connected to the land. The plurality of via holes are provided such that at least a part thereof is shifted by a given amount from the same position in a stacking direction to a planar direction of the multilayer board. For this reason, the insulating board and the interlayer connecting materials are dispersed to some extent. Therefore, stress (stress caused based on the difference between coefficients of linear thermal expansion of the insulating board and the interlayer connecting materials) acting in the stacking direction on joining portions (joining portion between the land and the joining material and joining portion between the joining material and the electronic part) can be smaller compared with a case in which all the plurality of via holes are formed in succession at the same position in the stacking direction. That is to say, occurrence of stripping at the joining sections can be suppressed and the circuit board can be improved in the reliability of connection.

Japanese Laid Open Patent Application (JP-P2005-39044A) discloses a printed board in which a plurality of conductor patterns are arranged in the form of multiple layers in thermoplastic resin. The conductor patterns are electrically connected to each other through a plurality of interlayer connecting materials respectively filled in a plurality of via holes. The plurality of via holes include a first via hole which penetrates one of the plurality of conductor patterns and a second via hole having an opening portion facing to an opening portion of the penetrated conductor pattern and the surrounding of the opening portion. The interlayer connecting material filled in the second via hole is joined to the interlayer connecting material filled in the first via hole and to the surrounding of the opening portion of the penetrated conductor pattern. In the case of this printed board, since a conductor pattern is provided in the surrounding of the joining portion between the interlayer joining materials in the first and second via holes, the joining between the joining materials is secured even when misalignment occurs between the first via hole and the second via hole. That is to say, this printed board is improved in the reliability of connection.

Japanese Laid Open Patent Application JP-P2004-22670A discloses a manufacturing method of a multilayer ceramic board. This manufacturing method includes a step for manufacturing a first green sheet and a second green sheet different from each other in thermal contraction coefficient, a step for forming a via hole for adjusting the thermal contraction coefficient in the second green sheet, a step for burying material for adjusting the thermal contraction coefficient in the via hole for adjusting the thermal contraction coefficient, and then a step for converting the first green sheet into a first ceramic dielectric layer and converting the second green sheet into a second ceramic dielectric layer by stacking the first green sheet and the second green sheet and baking them. According to this manufacturing method, the difference between thermal contractions of the first green sheet and the second green sheet is reduced by adjusting the thermal contraction of entire the second green sheet based on the thermal contraction of the material for adjusting the thermal contraction coefficient. Consequently, cracks and delamination in the first and second ceramic dielectric layers are prevented and the quality of the multilayer ceramic board is improved.

Japanese Laid Open Patent Application (JP-P2003-318322A) discloses an interposer board for mounting a semiconductor chip on the front surface. The interposer board has a plurality of wiring boards. The plurality of wiring boards are stacked such that stress relaxation layers are positioned between adjacent wiring boards, and adjacent wiring boards are electrically connected to each other to form a circuit. Each of the plurality of wiring boards is a double-sided board or a multilayer board. In at least one of combinations of the adjacent wiring boards, the wiring boards have areas different from each other and one of the wiring boards is positioned on the side closer to the front surface without protruding from the other. According to this interposer board, stress concentration is relaxed when a semiconductor chip is mounted face down on the interposer board.

However, as for the method disclosed in Japanese Laid Open Patent Application (JP-A-Heisei 10-084186), there is a problem that fine pitch is difficult, since it is necessary to consider the alignment between the positions of the wiring pattern and the holes in which conductors buried. In addition, although it is described that not only conductive paste but also metal bodies such as solder balls and gold balls can be used as the conductors forming vias, it is actually difficult to fill the metal bodies into the fine-pitch and small via holes only by using a printing method. Moreover, when metal balls with a diameter of 100 μm or below are arrayed, there is a problem that short circuits between vias are likely to be caused since the metal balls pull each other due to electrostatic force. There is also a problem that an open fault due to the removal of the metal balls is likely to be caused.

According to Japanese Laid Open Patent Application (JP-P2003-60348A), resin layers with conductor patterns formed on the respective single sides are stacked to form a printed board and vias are filled only with conductive paste. For this reason, there is a problem that via formation has to depend on a printing method and formation of fine-pitch wirings is difficult. Moreover, since entire the resin layers are formed of the same material, there is also a problem that destruction of a flip-chip bump, destruction of resin inside the board and the like may be caused due to the difference in thermal expansion coefficient between silicon and adhering resin in the case of flip-chip connection of an LSI chip and the like to the board.

According to the method disclosed in Japanese Laid Open Patent Application (JP-P2003-188536A), a large number of processes such as supply of a dielectric layer and flattening are necessary since the structure requires that the dielectric layer be provided in a place without a conductor pattern in a sticking surface for stacking and the whole surface be flattened, leading to increase in costs as a result. There is also a problem that since this dielectric layer is arranged between an adhesion layer and a stacked plate, a larger number of interface between different materials present than usual and reliability at the adhesion surface is deteriorated. In addition, resin with an excellent mechanical property cannot be used when photosensitive resin is used. When an organic board and an inorganic board are stuck together, there is a problem that the difference in thermal expansion coefficient is large and reliability cannot be obtained. There is also a problem that fine pitch is difficult only by stacking double-sided wiring boards.

In the method disclosed in Japanese Laid Open Patent Application (JP-P2004-228165A), there is a problem that since a mounting section for electronic parts and a motherboard printed board are formed of the same resin, reliability can be deteriorated depending on the parts to be mounted. There is also a problem that material cost is high because all dielectric layers are formed of thermoplastic polyimide. Moreover, there is a problem that an electricity cost for heating is high because high temperature is required in sticking. In addition, since all vias are filled with conductive paste and a hole for the escape of air is provided in a conductive layer, there are problems that a process for providing this hole is necessary and a defect such as crack from the hole is likely to be caused. In addition, since a supporting plate is not used for the connection when boards with different external shapes are stuck, high pressure is required to stick the thin boards with different external shapes together in an island form and there is also a problem that a circuit board may have low reliability due to damage to insulating layers and conductive layers.

### DISCLOSURE OF INVENTION

The present invention was achieved in view of the above problems. An object of the present invention is to provide a wiring board for mounting semiconductor device, which is effective for an increase in terminals and finer pitch of terminal intervals due to an improvement in integration, performance or multi-function of semiconductor devices, can mount semiconductor devices especially on both sides of the board at a high density and high accuracy, and is excellent in reliability; a manufacturing method of the same; and a wiring board assembly.

A wiring board for mounting semiconductor device according to the present invention includes a dielectric film, wirings formed in the dielectric film, a plurality of electrode pads provided at front and back surfaces of the dielectric film with their surfaces being exposed and with at least portions of lateral sides of them being buried into the dielectric film, and vias connecting the wirings and the electrode pads. At least one via connecting each other the wirings formed in the dielectric film includes second material different from first material forming the vias connecting the wiring and the electrode pads. Since the electrode pads at both front and back sides of the wiring board are buried in the dielectric film, variation in the heights of the electrode pads can be suppressed at both the front and back sides and semiconductor devices can be mounted on both sides of the wiring board at a high density and high accuracy. In addition, since the lateral sides of the electrode pads are buried in the dielectric film, a wiring board for mounting semiconductor device can be obtained which has improved adhesion between the electrode pads and the dielectric film and is excellent in reliability for connection to semiconductor devices.

It is preferable that the dielectric film includes a first dielectric layer positioned at a front surface of the wiring board, a second dielectric layer positioned at a back surface of the wiring board and one or a plurality of third dielectric layers positioned inside the wiring board. In this case, a plurality of wirings buried in both surfaces of the third dielectric layers and vias connecting the plurality of wirings are provided to the third dielectric layers. The electrode pads are provided with surfaces thereof being exposed at a surface of the first dielectric layer at a front surface side of the wiring board and at a surface of the second dielectric layer at a back surface side of the wiring board, and at least the portions of the lateral sides of the electrode pads are buried in the first dielectric layer or the second dielectric layer. At least one via connecting the plurality of wirings buried at the both surfaces of the third dielectric layers includes second material different from first material forming vias formed in the first dielectric layer and the second dielectric layer.

The wiring board for mounting semiconductor device has a structure in which the vias are provided and the wirings are buried at the front and back surfaces of the third dielectric layer positioned inside the wiring board for mounting semiconductor device, the first dielectric layer is formed at the front side of the third dielectric layer and the second dielectric layer is formed at the back side of the third dielectric layer. Therefore, it is possible to prevent a problem of stripping at each interlayer interface of the dielectric film and further improve reliability of the wiring board for mounting semiconductor device, even when a heat load and a bias due to the operation of a semiconductor device is repeatedly applied. This solves a problem that because a conventional wiring board has a structure in which wirings are provided to the front and back surfaces of a dielectric film positioned inside, stripping at the interface of the dielectric film develops especially in the case of a highly-multilayered structure when stress to strip the interface of the dielectric film is generated due to a heat load caused by the operation of a semiconductor device.

As mentioned above, the wiring board for mounting semiconductor device according to the present invention has an advantage that since each interlayer interface of the dielectric film will not be stripped due to the structure, dielectric films with different physical properties can be combined and the wiring board for mounting semiconductor device can be optimized in accordance with a use. In particular, even when a fourth dielectric layer having a wiring and a via is formed between the first dielectric layer and the third dielectric layer or between the second dielectric layer and the third dielectric layer, reliability in practical use can be secured because stripping at the Interlayer interface between the third dielectric layer and the fourth dielectric layer is prevented due to the structure.

In addition, it is preferable that the vias connecting the plurality of wirings buried in the both surfaces of the third dielectric layers includes a via which connects wirings most remote from the first dielectric layer and the second dielectric layer and includes second material different from first material forming the rest vias.

For example, the second material may be conductive paste or solder paste, and also may be conductive paste or solder paste including two or more kinds of powder particles.

In addition, it is preferable that the second material should include at least one kind of powder particles of tin, bismuth, indium, copper, silver, zinc, gold, nickel, antimony, copper coated with silver, zinc coated with silver, organic filler coated with silver, and organic filler coated with tin in conductive paste or solder paste. Although there is disadvantage in some cases in terms of heat resistance when the solder paste is formed of metal with a low melting point, mixing these powder particles into the paste can improve the reliability of the via for connection.

In addition, the second material can includes at least one kind of powder particles including as a parent phase at least one kind of alloy selected from a group of tin-bismuth binary alloy, tin-indium binary alloy, tin-zinc binary alloy, tin-silver binary alloy, tin-copper binary alloy, tin-gold binary alloy, tin-antimony binary alloy, and tin-nickel binary alloy in conductive paste or solder paste. An optimum alloy can be selected depending on a press temperature below heat resistant temperature of resin forming the wiring board.

It is preferable that the inside portion of the via formed of the second material should include a portion of a shape of a bulk and the bulk includes at least one kind of element selected from a group of tin, bismuth, indium, copper, silver, zinc, gold and nickel.

Furthermore, it is preferable that the powder particles form a metal joining layer in the via formed of the second material.

Additionally, the first material can includes at least one kind of metal selected from a group of copper, nickel and gold.

Among the first dielectric layer, the second dielectric layer and the third dielectric layer, at least the first dielectric layer and the second dielectric layer may be formed of different materials. Concerning to specific effects of combining different dielectric layers, in the case that at least one of the first dielectric layer and the second dielectric layer is formed of material having film strength higher than the third and fourth dielectric layers, it is possible to prevent the occurrence of crack from the surface of the wiring board due to the difference in thermal expansion coefficient during mounting a semiconductor device. Additionally, when at least one of the first dielectric layer and the second dielectric layer is formed of material having a thermal expansion coefficient lower than those of the third and fourth dielectric layers, or when at least one of the first dielectric layer and the second dielectric layer is formed of material having an elastic modulus lower than those of the third and fourth dielectric layers, it is possible to reduce stress to the mounted semiconductor device and a motherboard mounting the wiring board for mounting semiconductor device according to the present invention, and improve reliability of entire module equipment.

Furthermore, it is possible to apply different materials to the first dielectric layer and the second dielectric layer, and easily combine the best dielectric layers in terms of reliability according to a use. For example, material with film strength higher than those of the third and fourth dielectric layers is applied to the first dielectric layer in order to prevent the occurrence of crack from the surface of the wiring board due to difference in thermal expansion coefficient during mounting a semiconductor device, and material with an elastic modulus lower than those of the third and fourth dielectric layers is applied to the second dielectric layer in order to reduce stress to the motherboard.

In addition, it is also possible to provide at least one layer of a fourth dielectric layer including a wiring and a via at least one of positions between the first dielectric layer and the third dielectric layer and between the second dielectric layer and the third dielectric layer.

Additionally, an external shape of at least one dielectric layer of a dielectric layer at an upper side of the third dielectric layer and a dielectric layer at a lower side of the third dielectric layer is different from an external shape of the third dielectric layer.

The external shape of one dielectric layer of the dielectric layer at the upper side of the third dielectric layer and the dielectric layer at the lower side of the third dielectric layer may be the same as the external shape of the third dielectric layer, and the external shape of the other dielectric layer of the dielectric layer at the upper side of the third dielectric layer and the dielectric layer at the lower side of the third dielectric layer may be smaller than the external shape of the third dielectric layer. Consequently, a reduction in the volume of the board is possible even when a place necessary to be multilayered and a place unnecessary to be multilayered are present.

It is also possible to further provide, on a surface of the third dielectric layer, which comes into contact with the other dielectric layer, at least one layer of the other dielectric layer.

It is preferable that at least one dielectric layer of the first, second, and fourth dielectric layers include a wiring layer of inorganic material and the third dielectric layer be formed of organic material.

The third dielectric layer may include epoxy resin.

The third dielectric layer may include polyimide resin.

The third dielectric layer may include acrylic resin.

The third dielectric layer may include glass cloth.

The third dielectric layer may include silica filler.

The third dielectric layer may include aramid nonwoven fabric.

The third dielectric layer may include thermosetting resin.

The third dielectric layer may include thermoplastic resin.

The third dielectric layer may include photosensitive resin. The third dielectric layer in which the via filled with conductive paste or solder paste also serves as an adhesion layer in the pressing. For this reason, when considering the reliability after cure, material of the third dielectric layer can be selected from epoxy resin, polyimide resin, acrylic resin, acrylic resin, resin including glass cloth, resin including silica filler, and resin including aramid nonwoven fabric, depending on press temperature. In view of properties too, it is possible to select any of thermosetting resin and thermoplastic resin depending on the process. Furthermore, photosensitive resin can be used when the via hole is required to be formed by a method which is independent on laser or a drill.

An exposed surface of at least one of the plurality of electrode pads may be arranged at the same level of the front surface or the back surface of the dielectric film. According to this structure, when semiconductor devices are electrically connected through gold bumps or the like, a wiring board assembly is provided in which the connections of finer pitch and higher accuracy are achieved.

In addition, an exposed surface of at least one of the plurality of electrode pads may be depressed from the front surface or the back surface of the dielectric film. According to this structure, when semiconductor devices are mounted by using wire bonding or solder, a wiring board assembly is provided in which connections of finer pitch and higher accuracy are achieved.

Additionally, an exposed surface of at least one of the plurality of electrode pads may protrude from the front surface or the back surface of the dielectric film. According to this structure, breaking cracks of solder balls can be prevented and a wiring board assembly with further excellent reliability can be provided when the solder balls are mounted on the protruding surface and a motherboard mounts the board.

A surface of at least one of said plurality of electrode pads may be partially covered by the dielectric film. In the wiring board for mounting semiconductor device having the structure, since almost all portions of the pad is buried in resin, crack is not likely to occur from the end of the pad and the board is excellent in reliability. In addition, since the dielectric layer after the formation of an opening serves as a solder resist, the solder resist layer can be formed which is stable due to good adhesion with metal forming the pad and the wiring compared with a method to form a solder resist after the etching of a supporting body. Furthermore, the opening can be formed above the pad with high precision in position since the opening can be formed above the pad after checking the position of the pad.

It is also possible to provide a supporting body on at least a portion of the front surface or the back surface of the dielectric film.

It is also possible to provide a solder resist layer on at least one of the front surface or the back surface of the dielectric film.

A semiconductor device according to the present invention is provided by mounting semiconductor elements on the above-mentioned wiring board for mounting semiconductor device.

A manufacturing method of wiring board for mounting semiconductor device according to the present invention includes a step for forming a first wiring board, a step for forming a second wiring board and a step for sticking a dielectric layer forming an uppermost surface of the first wiring board and a dielectric layer forming an uppermost surface of the second wiring board together face to face after the formation of the first wiring board and the second wiring board. The step for forming the first wiring board includes a first step for forming a conductive layer to be an electrode pad, a second step for forming a dielectric layer on the conductive layer, a third step for forming a via in the dielectric layer, a forth step for forming a wiring layer on the dielectric layer, a fifth step for forming another dielectric layer on the wiring layer, and a sixth step for repeating the third to fifth steps for one or plurality of times as necessary. The step for forming the second wiring board includes a first step for forming a conductive layer to be an electrode pad, a second step for forming a dielectric layer on the conductive layer, a third step for forming a via in the dielectric layer, a forth step for forming a wiring layer on the dielectric layer, a fifth step for forming another dielectric layer on the wiring layer, a sixth step for repeating the third to fifth steps for one or plurality of times as necessary, a seventh step for forming a via in the dielectric layer forming the uppermost surface and burying a conductor therein. The manufacturing method of wiring board for mounting semiconductor device according to the present invention includes a step for burying first material into vias in dielectric layers of the first and second wiring boards and a step for filling second material different from the first material in the step for forming the dielectric layer forming the uppermost surface of the second dielectric layer.

Additionally, a step for forming the first wiring board can includes a seventh step for forming a via in the dielectric layer forming the uppermost surface and burying a conductor therein.

The step for forming the first wiring board and/or the step for forming the second wiring board can include a step for forming the conductive layer to be the electrode pad on a supporting base and a step for removing the supporting base entirely or partially can be performed after the step for sticking.

The step for forming the dielectric layer forming the uppermost layer preferably includes a step for filling conductive paste or solder paste in a via.

The step for forming the dielectric layer forming the uppermost layer may include a step for filling conductive paste or solder paste in a via by using a printing method.

The step for forming the dielectric layer forming the uppermost layer preferably includes a step for forming a via by using laser or a drill in a resin sheet to be a portion of the dielectric layer.

The step for forming the dielectric layer forming the uppermost layer may include a step for forming a via in the dielectric layer by using development by exposure.

Various shapes can be selected for vias included in the wiring board and the wiring board assembly according to the present invention. Examples are a cylindrical shaped via with the front-surface and back-surface sides of the same size, a potbelly shaped via with the front-surface and back-surface sides of the same size and the swelled middle, a hourglass shaped via with the narrowed middle, and a conical shaped via. The cylindrical shaped via has an advantage that the via is easily formed by using a drill or the like. The potbelly shaped via has advantages that electrical resistance is small due to the swelled middle and a wiring density in a wiring portion can be higher compared with the case of cylindrical via because of the smaller size at the ends of the via than at the middle. The hourglass shaped via with the narrowed middle has an advantage that reliability is improved due to the wider areas at the ends of the via, which are connecting portions with wirings. Generally, the connection at the connecting portions is likely to be week. Concerning to a laser via formed by using laser and a photo via formed by using light, the diameter of the via is tend to be large at the side of incidence of laser or light. The shapes of them can be controlled to some extent by selecting material, irradiation conditions of laser and light, exposure condition and the like.

The step for sticking the dielectric layers forming the uppermost surfaces together face to face can include a step for having metal powder particles metal-joined in the conductive paste or solder paste.

When the conductive paste or solder paste includes a metal powder with melting temperature below press temperature, metal joining is possible as a result of melting of the metal powder and elemental diffusion to the adjacent metal powder during the pressing in which load and temperature is applied. When all the metal powders inside the via have melting points below press temperature, a bulk shape is formed in the via. At this time, wettability between the powders differs depend on the activity of binder and flux used in the conductive paste or solder paste In the case of poor wettability, metal joining partly occurs at the interface between the metal particles as a result of elemental diffusion.

A via filled with conductive paste or solder paste and coming into contact with wiring layers of two boards with supporting plates to be stuck together also serves to remove oxide films formed at the surfaces of the wiring layers of the boards. The thickness of the intermetallic compound layer such as Cu—Sn, Sn—An, Au—Zn or Cu—Zn formed between the powder and the electrode is different due to the activity of binder and flux used in the conductive paste or solder paste. Even when the activities of binder and flux are low, an oxide film can be destructed by the pressing forces between the powders and between the powder and the electrode during the pressing. In this way, via connection with high reliability is possible.

When all the metal powders in the conductive paste or solder paste have melting temperatures above press temperature, the metal powders do not melt during the pressing in which load and temperature are applied. However, metal joining is possible at the interface of the metal particle as a result of elemental diffusion between adjacent metal powders. Even when the activities of binder and flux are low, an oxide film can be destructed by the pressing forces between the powders and between the powder and the electrode during the pressing, and thus the elemental diffusion is facilitated. In this way, via connection with high reliability is possible.

Another manufacturing method of wiring board for mounting semiconductor device according to the present invention, includes a step for forming two wiring boards by performing a first step for forming a conductive layer to be an electrode pad, a second step for forming a dielectric layer on the conductive layer, a third step for forming a via in the dielectric layer, a forth step for forming a wiring layer on the dielectric layer and a fifth step for forming a wiring layer as an uppermost layer by repeating the second step to the forth step for one or a plurality of times as necessary; a sixth step for forming a via in another dielectric layer by using laser or a drill; and a seventh step for sticking the wiring layer as the uppermost layer of each of the two wiring boards with the via formed in the other dielectric layer together such that the other dielectric layer is put between the two wiring boards face to face.

The step for forming the two wiring boards can also includes a step for forming the conductive layer to be the electrode pad on a supporting base for at least one of the boards. A step for removing the supporting base entirely or partially can be included after the step for sticking. In this case, the supporting base can be a metal plate. The electrode pads are formed on the first and second supporting bases such as metal plates and the first and second dielectric films are formed on the electrode pads on the first and second supporting bases respectively. After that, the first and second dielectric films are stuck together, and then a dielectric film is formed by removing the first and second supporting plates. In this cases since the electrode pads are formed on the first and second supporting base with excellent flatness, exposed surfaces of the electrode pads are positioned accurately and densification is facilitated.

Additionally, since the two wiring boards formed on the supporting bases are stuck together face to face, the wiring board for mounting semiconductor device can be formed which is more accurate in alignment in the sticking, and more excellent in densification and reliability compared with a conventional simultaneously-stacked multilayer wiring board formed by simultaneously stacking a plurality of resin sheets. There is also an advantage that the number of layers can be increased in a short period of time compared with a conventional build-up board.

When stacking is performed at too high temperature and too high pressure in the sticking the two wiring boards formed on the supporting bases together face to face, there is a problem that reliability is deteriorated as a result of the occurrence of distortion of the wiring boards formed in advance on the supporting bases. In the case of the wiring board for mounting semiconductor device according to the present invention, the flatness is achieved by forming the dielectric layers at the uppermost layers, conductors such as conductive paste or solder paste are buried in the vias formed in the dielectric layers, and thus the vias in which the conductors are buried is stacked to obtain an electrical connection. Since flat surfaces are stuck together, the two wiring boards formed on the supporting bases can be stuck together face to face even at the condition of low temperature and low pressure, and thus the wiring board for mounting semiconductor device can be obtained which is excellent in accuracy and reliability.

It is also possible to manufacture a board with supporting plate and connect it to a conventional inorganic or organic circuit board by pressing. As a result, it is possible to add a circuit necessary due to a circuit design to a commercially-available circuit board.

According to the present invention, since a multilayer circuit board on a supporting plate, which include a via formed by a plating method, dielectric resin and an electrode is used and connection for conductive portions are obtained by filling conductive paste or solder paste in the via portion, a multilayer board is formed which enables the formation of circuit wiring with finer pitch therein, is more excellent in electrical properties at high speed and high frequency, is thinner, and has larger number of layers compared with a simultaneously-stacked board. Additionally, when a circuit board having a number of layers is formed, a tact time is shortened and a yield is improved by manufacturing circuit boards each having the half number of layers at the same time, sticking the circuit boards through a resin dielectric layer and a via filled with conductive paste or solder paste.

### BRIEF DESCRIPTION OF DRAWINGS

FIG. 1 is a cross-sectional view showing a wiring board for mounting semiconductor device according to a first exemplary embodiment of the present invention;

FIG. 2A is a cross-sectional view showing a modification example of the wiring board for mounting semiconductor device according to the first exemplary embodiment;

FIG. 2B is a cross-sectional view showing a modification example of the wiring board for mounting semiconductor device according to the first exemplary embodiment;

FIG. 2C is a cross-sectional view showing a modification example of the wiring board for mounting semiconductor device according to the first exemplary embodiment;

FIG. 3A is a cross-sectional view showing still another modification example of the wiring board for mounting semiconductor device according to the first exemplary embodiment;

FIG. 3B is a cross-sectional view showing still another modification example of the wiring board for mounting semiconductor device according to the first exemplary embodiment;

FIG. 4A is a cross-sectional view showing still another modification example of the wiring board for mounting semiconductor device according to the first exemplary embodiment;

FIG. 4B is a cross-sectional view showing the other modification example of the wiring board for mounting semiconductor device according to the first exemplary embodiment;

FIG. 4C is a cross-sectional view showing the other modification example of the wiring board for mounting semiconductor device according to the first exemplary embodiment;

FIG. 5A is a cross-sectional view showing a wiring board assembly according to a second exemplary embodiment of the present invention;

FIG. 5B is a cross-sectional view showing a wiring board assembly according to the second exemplary embodiment of the present invention;

FIG. 5C is a cross-sectional view showing a wiring board assembly according to the second exemplary embodiment of the present invention;

FIG. 6A is a cross-sectional view showing a wiring board for mounting semiconductor device according to a third exemplary embodiment of the present invention;

FIG. 6B is a cross-sectional view showing a wiring board for mounting semiconductor device according to the third exemplary embodiment of the present invention;

FIG. 7 is a cross-sectional view showing a wiring board for mounting semiconductor device according to a fourth exemplary embodiment of the present invention;

FIG. 8 is a cross-sectional view showing a wiring board for mounting semiconductor device according to a fifth exemplary embodiment of the present invention;

FIG. 9 is a cross-sectional view showing a wiring board for mounting semiconductor device according to a sixth exemplary embodiment of the present invention;

FIG. 10A is a cross-sectional view illustrating a manufacturing method of the wiring board for mounting semiconductor device according to the first exemplary embodiment of the present invention;

FIG. 10B is a cross-sectional view illustrating the manufacturing method of the wiring board for mounting semiconductor device according to the first exemplary embodiment of the present invention;

FIG. 10C is a cross-sectional view illustrating the manufacturing method of the wiring board for mounting semiconductor device according to the first exemplary embodiment of the present invention;

FIG. 10D is a cross-sectional view illustrating the manufacturing method of the wiring board for mounting semiconductor device according to the first exemplary embodiment of the present invention;

FIG. 10E is a cross-sectional view illustrating the manufacturing method of the wiring board for mounting semiconductor device according to the first exemplary embodiment of the present invention;

FIG. 11A is a cross-sectional view illustrating the manufacturing method of the wiring board for mounting semiconductor device according to the first exemplary embodiment of the present invention;

FIG. 11B is a cross-sectional view illustrating the manufacturing method of the wiring board for mounting semiconductor device according to the first exemplary embodiment of the present invention;

FIG. 11C is a cross-sectional view illustrating the manufacturing method of the wiring board for mounting semiconductor device according to the first exemplary embodiment of the present invention;

FIG. 11D is a cross-sectional view illustrating the manufacturing method of the wiring board for mounting semiconductor device according to the first exemplary embodiment of the present invention;

FIG. 12A is a cross-sectional view showing a modification example of the wiring board for mounting semiconductor device according to the first exemplary embodiment of the present invention;

FIG. 12B is a cross-sectional view showing the modification example of the wiring board for mounting semiconductor device according to the first exemplary embodiment of the present invention;

FIG. 12C is a cross-sectional view showing the modification example of the wiring board for mounting semiconductor device according to the first exemplary embodiment of the present invention;

FIG. 13A is a cross-sectional view showing another modification example of the wiring board for mounting semiconductor device according to the first exemplary embodiment of the present invention;

FIG. 13B is a cross-sectional view showing the other modification example of the wiring board for mounting semiconductor device according to the first exemplary embodiment of the present invention;

FIG. 14A is a cross-sectional view illustrating the manufacturing method of the wiring board for mounting semiconductor device according to the first exemplary embodiment of the present invention;

FIG. 14B is a cross-sectional view illustrating the manufacturing method of the wiring board for mounting semiconductor device according to the first exemplary embodiment of the present invention;

FIG. 14C is a cross-sectional view illustrating the manufacturing method of the wiring board for mounting semiconductor device according to the first exemplary embodiment of the present invention;

FIG. 14D is a cross-sectional view illustrating the manufacturing method of the wiring board for mounting semiconductor device according to the first exemplary embodiment of the present invention;

FIG. 15A is a cross-sectional view illustrating the manufacturing method of the wiring board for mounting semiconductor device according to the first exemplary embodiment of the present invention;

FIG. 15B is a cross-sectional view illustrating the manufacturing method of the wiring board for mounting semiconductor device according to the first exemplary embodiment of the present invention;

FIG. 15C is a cross-sectional view illustrating the manufacturing method of the wiring board for mounting semiconductor device according to the first exemplary embodiment of the present invention;

FIG. 16A is a cross-sectional view illustrating a manufacturing method of the wiring board for mounting semiconductor device according to the first exemplary embodiment of the present invention;

FIG. 16B is a cross-sectional view illustrating the manufacturing method of the wiring board for mounting semiconductor device according to the first exemplary embodiment of the present invention;

FIG. 16C is a cross-sectional view illustrating the manufacturing method of the wiring board for mounting semiconductor device according to the first exemplary embodiment of the present invention;

FIG. 16D is a cross-sectional view illustrating the manufacturing method of the wiring board for mounting semiconductor device according to the first exemplary embodiment of the present invention;

FIG. 16E is a cross-sectional view illustrating the manufacturing method of the wiring board for mounting semiconductor device according to the first exemplary embodiment of the present invention;

FIG. 16F is a cross-sectional view illustrating the manufacturing method of the wiring board for mounting semiconductor device according to the first exemplary embodiment of the present invention;

FIG. 16G is a cross-sectional view illustrating the manufacturing method of the wiring board for mounting semiconductor device according to the first exemplary embodiment of the present invention;

FIG. 16H is a cross-sectional view illustrating the manufacturing method of the wiring board for mounting semiconductor device according to the first exemplary embodiment of the present invention;

FIG. 16I is a cross-sectional view illustrating the manufacturing method of the wiring board for mounting semiconductor device according to the first exemplary embodiment of the present invention;

FIG. 17A is a cross-sectional view illustrating the manufacturing method of the wiring board for mounting semiconductor device according to the first exemplary embodiment of the present invention;

FIG. 17B is a cross-sectional view illustrating the manufacturing method of the wiring board for mounting semiconductor device according to the first exemplary embodiment of the present invention;

FIG. 18A is a cross-sectional view illustrating the manufacturing method of the wiring board for mounting semiconductor device according to the first exemplary embodiment of the present invention;

FIG. 18B is a cross-sectional view illustrating the manufacturing method of the wiring board for mounting semiconductor device according to the first exemplary embodiment of the present invention;

FIG. 19A is a cross-sectional view illustrating the manufacturing method of the wiring board for mounting semiconductor device according to the first exemplary embodiment of the present invention;

FIG. 19B is a cross-sectional view illustrating the manufacturing method of the wiring board for mounting semiconductor device according to the first exemplary embodiment of the present invention;

FIG. 20A is a cross-sectional view illustrating a manufacturing method of a wiring board for mounting semiconductor device according to a seventh exemplary embodiment of the present invention;

FIG. 20B is a cross-sectional view illustrating the manufacturing method of the wiring board for mounting semiconductor device according to the seventh exemplary embodiment of the present invention;

FIG. 21A is a cross-sectional view illustrating a manufacturing method of a wiring board for mounting semiconductor device according to an eighth exemplary embodiment of the present invention;

FIG. 21B is a cross-sectional view illustrating the manufacturing method of the wiring board for mounting semiconductor device according to the eighth exemplary embodiment of the present invention;

FIG. 22A is a cross-sectional view illustrating a manufacturing method of a wiring board for mounting semiconductor device according to a ninth exemplary embodiment of the present invention;

FIG. 22B is a cross-sectional view illustrating the manufacturing method of the wiring board for mounting semiconductor device according to the ninth exemplary embodiment of the present invention;

FIG. 23A is a cross-sectional view illustrating a manufacturing method of a wiring board for mounting semiconductor device according to a tenth exemplary embodiment of the present invention;

FIG. 23B is a cross-sectional view illustrating the manufacturing method of the wiring board for mounting semiconductor device according to the tenth exemplary embodiment of the present invention;

FIG. 24A is a schematic diagram showing structures of powder particles inside conductive paste or solder paste obtained by the manufacturing method of the wiring board for mounting semiconductor device according to the present invention;

FIG. 24B is a schematic diagram showing structures of powder particles inside conductive paste or solder paste obtained by the manufacturing method of the wiring board for mounting semiconductor device according to the present invention;

FIG. 24C is a schematic diagram showing structures of powder particles inside conductive paste or solder paste obtained by the manufacturing method of the wiring board for mounting semiconductor device according to the present invention;

FIG. 24D is a schematic diagram showing a structure of a powder particle inside conductive paste or solder paste obtained by the manufacturing method of the wiring board for mounting semiconductor device according to the present invention;

FIG. 25A is a schematic diagram showing a state of structure of a powder particle coming into contact with an electrode wiring layer to be stuck;

FIG. 25B is a schematic diagram showing a state structure of the powder particle coming into contact with the electrode wiring layer to be stuck;

FIG. 25C is a schematic diagram showing a state of structure of the powder particle coming into contact with the electrode wiring layer to be stuck;

FIG. 26 is a cross-sectional view showing a conventional build-up board;

FIG. 27A is a cross-sectional view illustrating a manufacturing method of a conventional simultaneously-stacked multilayer wiring board;

FIG. 27B is a cross-sectional view illustrating the manufacturing method of the conventional simultaneously-stacked multilayer wiring board; and

FIG. 27C is a cross-sectional view illustrating the manufacturing method of the conventional simultaneously-stacked multilayer wiring board.

### BEST MODE FOR CARRYING OUT THE INVENTION

Exemplary embodiments of the present invention will be described in detail below with reference to the attached drawings. First, a first exemplary embodiment of the present invention will be described with reference to FIG. 1. FIG. 1 is a cross-sectional view showing a wiring board for mounting semiconductor device according to the present exemplary embodiment. In the wiring board for mounting semiconductor device, 5 according to the present exemplary embodiment, upper and lower wirings 2 and a via 3a for electrically connecting the upper and lower wirings 2 are provided in a dielectric film 1, and electrode pads 4 are provided to both the front and back surfaces of the wiring board for mounting semiconductor device, 5, namely, to both the front and back surfaces of the dielectric film 1. At least portion of the lateral side of the electrode pad 4 is buried in the dielectric film 1 and the wiring 2 and the electrode pad 4 are connected through a via 3. The wiring board for mounting semiconductor device, 5 is referred to as the board 5 in some cases.

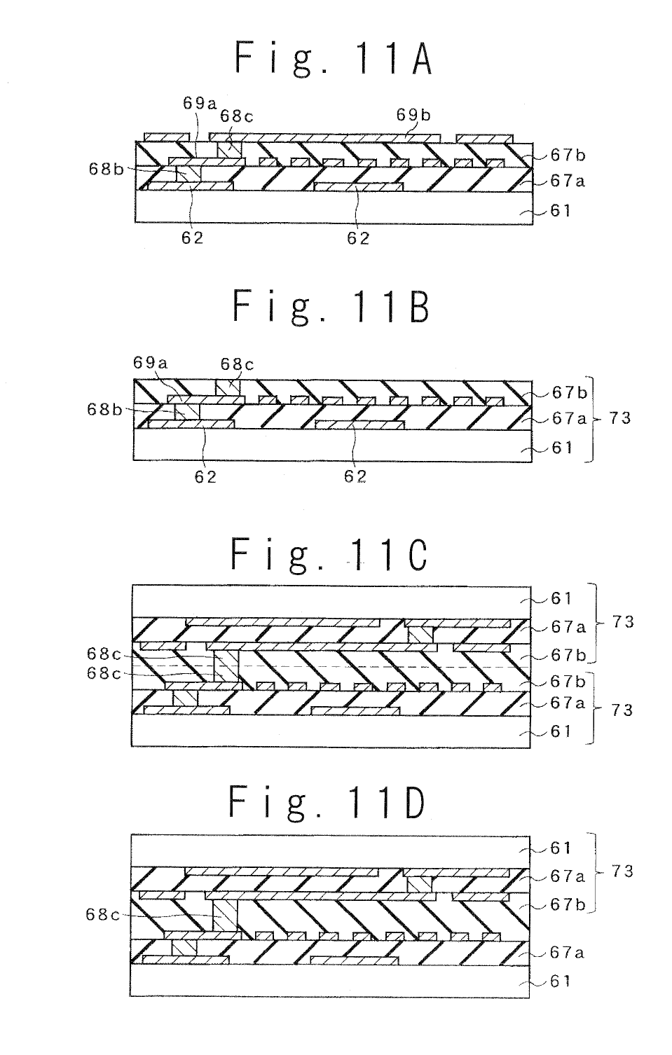

The dielectric film 1 is formed by stacking a plurality of dielectric layers (see dielectric layers 67a and 67b in FIG. 11A). The wirings 2 are provided by patterning a conductive film on each of the dielectric layers using a plating method. Before the plating process to form the wiring 2, a via hole which reaches the lower-layer wiring 2 is formed in the dielectric layer and the via 3 is formed by burying conductive material for forming the plated wiring into the via hole. In addition, the via 3a is formed by burying material different from the case of the via 3, e.g. conductive paste or lead-free solder paste, into a via hole for connecting the upper and lower wirings 2. Consequently, the via 3, which connects the wiring 2 and the electrode pad 4 is formed with the plating material for wiring, and the via 3a, which electrically connects the upper and lower wirings 2 is formed with the material different from the case of the via 3, e.g. conductive paste or solder paste.

Materials of the dielectric layers included in the dielectric film 1 are the same. The material of the dielectric film 1 is not limited to a specific material, if the material is excellent in heat resistance in soldering, high chemical resistance and so forth, but preferably is heat-resistant resin, such as epoxy resins polyimide, and liquid crystal polymer, which has high glass transition temperature and is excellent in mechanical properties such as film strength and elongation at break. When considering that costs, working temperature, and reliability are important, it is also possible to use epoxy resin, acrylic resin, polyimide, and so forth. When the thickness of the dielectric film 1 is 0.3 mm or below, it is preferable to use as the material of the dielectric film 1, a material with a high bending modulus such as impregnated glass cloth, impregnated aramid nonwoven fabric and so forth for the purpose of improved handling during mounting the semiconductor device.

Concerning the wiring board for mounting semiconductor device, 5 according to the present invention, since the electrode pads 4 on both the front and back surfaces of the board 5 are buried in the dielectric film 1, variations in the heights of the electrode pads 4 can be reduced at both the front and back surfaces of the board 5 and semiconductor devices can be mounted at high density and high accuracy on the both sides of the wiring board for mounting semiconductor device, 5. Furthermore, since the lateral sides of the electrode pads 4 are buried into the dielectric film 1, adhesion between the electrode pads 4 and the dielectric film 1 is improved and the wiring board for mounting semiconductor device, 5 having high connection reliability with the semiconductor devices can be obtained.

In addition, since the via 3 is formed by using the plating method, a work for arraying metal balls or the like is not required and fine patterns can be formed. Therefore, the vias can be arranged at fine pitch and a circuit board having a high wiring capacity can be formed compared with the cases of the boards disclosed in Japanese Laid Open Patent Application (JP-A-Heisei 10-084186), Japanese Laid Open Patent Application (JP-P2003-60348A), and Japanese Laid Open Patent Application (JP-P2004-228165A). Additionally, different from the disclosure in Japanese Laid Open Patent Application JP-P2004-228165A, it is not necessary to form a hole for the escape of air in the conductive layer in burying conductive paste or solder paste into the via hole, and thus the number of processes is reduced. Furthermore, since there is no hole for the escape of air, defects such as cracks from the hole are not occurred.

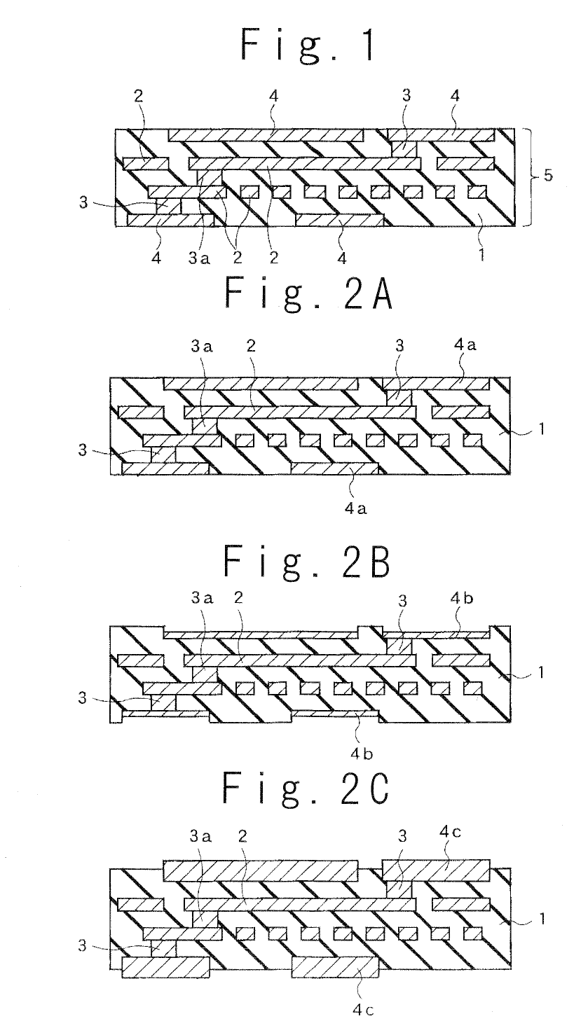

FIGS. 2A to 2C are cross-sectional views showing modification examples of the wiring board for mounting semiconductor device according to the present exemplary embodiment. The electrode pads 4 formed on both the front and back surfaces of the dielectric film 1 can be any of electrode pads 4a with their exposed surfaces at the same level as the front surface or the back surface of the dielectric film 1 as shown in FIG. 2A, electrode pads 4b with their exposed surfaces depressed from the front surface or the back surface of the dielectric film 1 as shown in FIG. 2B, and electrode pads 4c with their exposed surfaces protruding from the front surface or the back surface of the dielectric film 1 as shown in FIG. 2C.

When a semiconductor device is mounted by using gold bumps on the electrode pads 4a with their exposed surfaces at the same level as the front surface or the back surface of the dielectric film 1 as shown in FIG. 2A, connection of the semiconductor device at the highest accuracy and the most fine pitch can be achieved since no variations in the heights of the electrode pads 4a are present at all. When a semiconductor device is mounted by using gold wire bonding or solder on the electrode pads 4b with their exposed surfaces depressed from the front surface or the back surface of the dielectric film 1 as shown in FIG. 2B, connection of the semiconductor device at the highest accuracy and the most fine pitch can be achieved since the dielectric film 1 at the protruding level from the electrode pads 4b prevents excessive deformation of the gold or the solder. Furthermore, when solder balls are mounted on the electrode pads 4c with their exposed surfaces protruding from the front surface or the back surface of the dielectric film 1 as shown in FIG. 2C and the board is mounted on a motherboard, cracks from the base of the solder balls can be prevented and a wiring board assembly with higher reliability can be obtained.

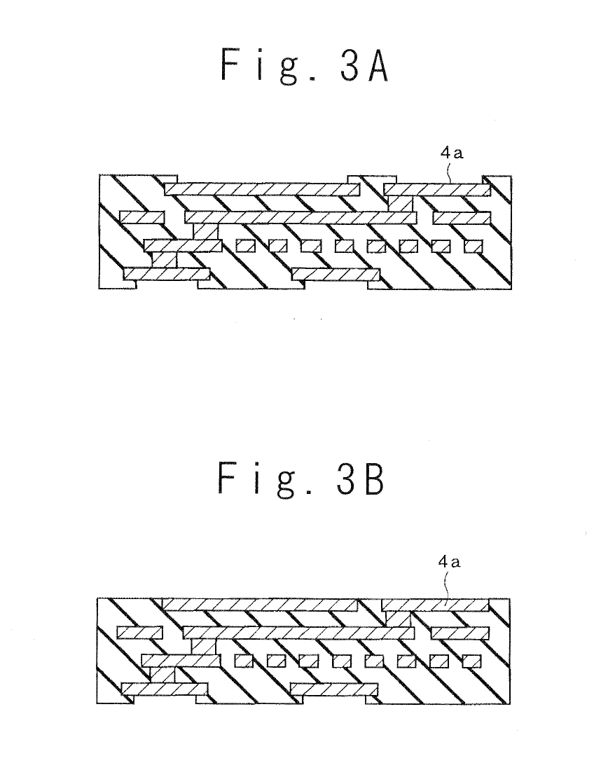

FIGS. 3A to 3B are cross-sectional views showing still another modification examples of the wiring board for mounting semiconductor device according to the present exemplary embodiment. As shown in FIG. 3A, surfaces of the electrode pads 4a formed at both the front and back surfaces of the dielectric film 1 are partly covered with the dielectric film 1. In FIG. 3B, on the other hand, the exposed surfaces of the electrode pads 4a formed at the back surface (lower side in the figure) are partly covered with the dielectric film 1, and the electrode pads 4a formed at the front surface (upper side in the figure) are arranged at the same level as the front surface of the dielectric film 1. In FIGS. 3A and 3B, the electrode pads 4a which are formed at the front surface or the back surface of the dielectric film 1 with their surfaces partly covered with the dielectric film 1 are depressed from the front surface or the back surface of the dielectric film 1, however, are not limited to that.

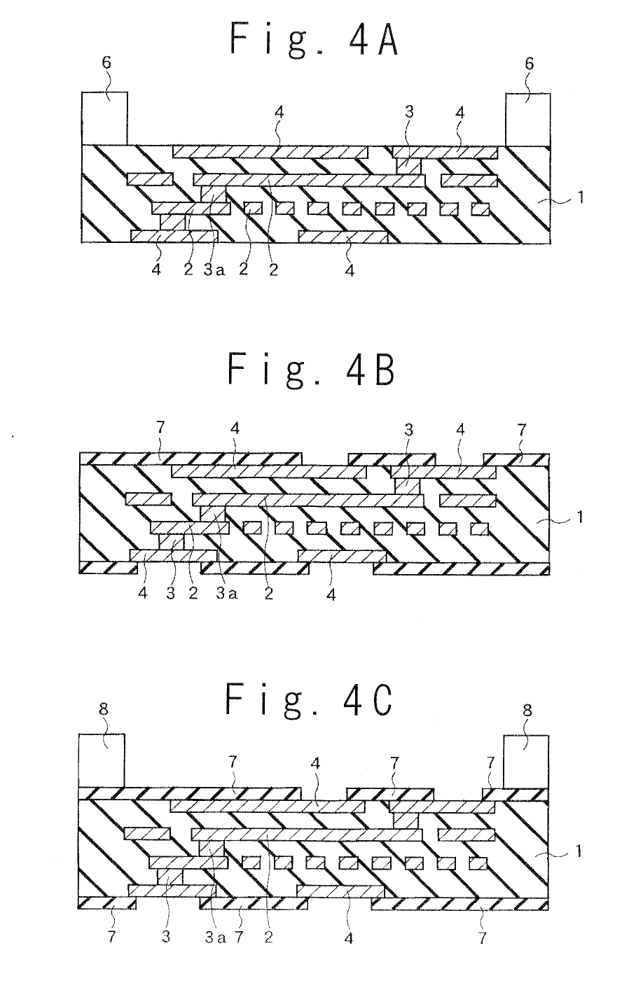

FIGS. 4A to 4C are cross-sectional views showing still another modification examples of the wiring board for mounting semiconductor device according to the present exemplary embodiment. Concerning the wiring board shown in FIG. 4A, a supporting body 6 is provided to at least portion of the front surface or the back surface of the dielectric film 1 of the wiring board for mounting semiconductor device, 5 according to the first exemplary embodiment of the present invention. By providing the supporting body 6, it is possible to reduce the warp, undulation and so forth of the wiring board for mounting semiconductor device, 5 due to a thermal history during mounting semiconductor devices and mount semiconductor devices at higher accuracy. It is also possible as shown in FIG. 4B, to form a solder resist 7 on at least one of the front and back surfaces of the dielectric film 1. In particular, since variations in the heights of the electrode pads 4 are extremely small in the case of the wiring board for mounting semiconductor device, 5 according to the present exemplary embodiment, the solder resist 7 can be formed at high accuracy. Furthermore, it is also possible to provide a supporting body 8 on at least portion of the surface of the solder resist 7 as shown in FIG. 4C.

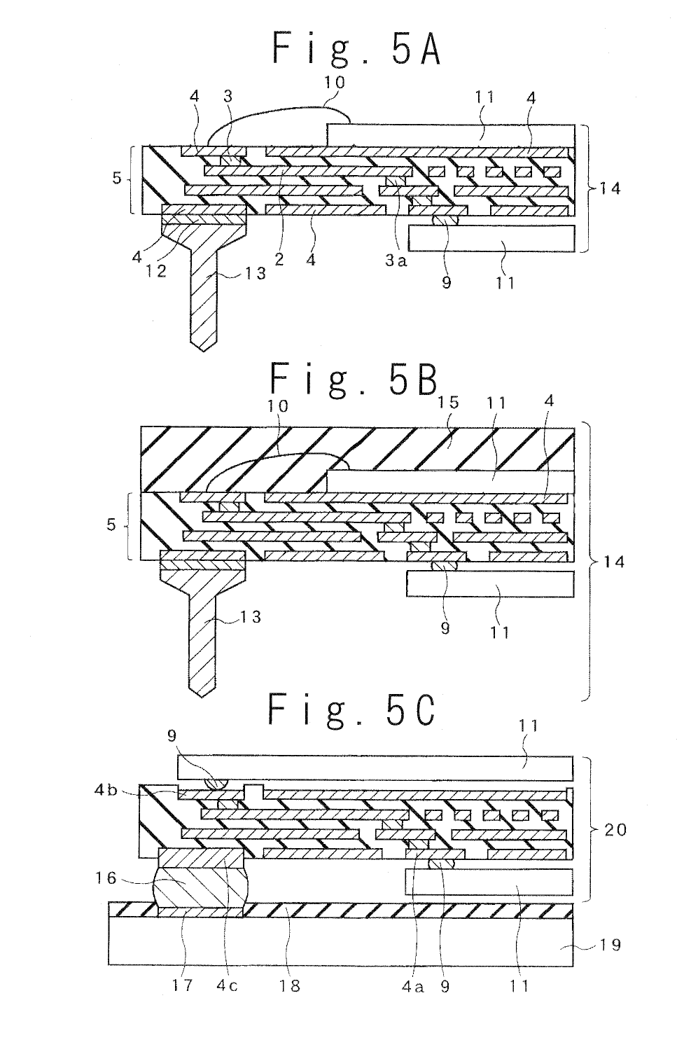

Next, printed wiring assemblies according to a second exemplary embodiment of the present invention will be described. FIGS. 5A to 5C are cross-sectional views showing the printed wiring assemblies according to the present exemplary embodiment. Concerning the wiring board assembly 14 according to the present exemplary embodiment as shown in FIG. 5A, two semiconductor devices 11 are mounted on the above-mentioned wiring board for mounting semiconductor device, 5. A bump 9 provided to the wiring board for mounting semiconductor device, 5 connects the electrode pad 4 and one semiconductor device 11. Furthermore, a terminal at one surface of the other semiconductor device 11 and the electrode pad 4 are connected with the semiconductor device 11 placed on the electrode pad 4 and a terminal at the other surface of the semiconductor device 11 and the electrode pad 4 are electrically connected through a bonding wire 10. In addition, as for this wiring board assembly 14, the electrode pad 4 and an external terminal pin 13 are connected through conductive bond 12 or the like. The bonding wire 10 is referred to as the wire 10 in some cases.

The electrode pad 4 provided at a place on which the semiconductor device 11 is mounted is either the electrode pad 4a of FIG. 2A as the electrode pad 4 with its exposed surface arranged at the same level as the front surface or the back surface of the dielectric film 1 or the electrode pad 4b of FIG. 2B with the exposed surface depressed from the front surface or the back surface of the dielectric film 1, and thus it is possible to achieve the wiring board assembly 14 of high-accuracy and high-density. The examples of mounting the semiconductor devices 11 by flip-chip connection using the bump 9 and wire bonding connection using the wire 10 have been described as the present exemplary embodiment. In addition, it is also possible to mount the semiconductor device 11 by using tape automated bonding, ribbon bonding method or the like.

Additionally, it is also possible as necessary, to form a molding 15 to cover the wire 10, the electrode pad 4 and the semiconductor device 11 connected through the wire 10 as shown in FIG. 5B.

A wiring board assembly 20 shown in FIG. 5C is mounted on a motherboard 19. The wiring board assembly 20 is referred to as the assembly 20 in some cases. The motherboard 19 includes at its surface, an electrode pad 17 and a solder resist 18. At the lower surface (back surface) of the wiring board assembly 20, the electrode pad 4c with its exposed surface protruding from the back surface of the dielectric film 1 is provided as shown in FIG. 2C. The assembly 20 is mounted on the motherboard 19 by connecting the electrode pad 17 of the motherboard to the electrode pad 4c through a solder ball 16. On the upper surface (front surface) of the wiring board assembly 20, the electrode pad 4b with its exposed surface depressed from the front surface of the dielectric film 1 is provided as shown in FIG. 2B. The semiconductor device 11 is mounted on the electrode pad 4b through the bump 9. On the lower surface (back surface) of the assembly 20, the electrode pad 4a is further provided with its exposed surface at the same level as the back surface of the dielectric film 1 as shown in FIG. 2A. The semiconductor device 11 is mounted on the electrode pad 4a through the bump 9. It is preferable that the electrode pad 4 to which the semiconductor device 11 is connected through the bump 9 should be the electrode pad 4a or 4b. It is preferable that the electrode pad 4 provided at the place on which the solder ball 16 is provided should be the electrode pad 4a or 4c. As a result, the wiring board assembly 14 can be obtained which can mount the semiconductor devices 11 at high density and high accuracy, further prevent cracks from the base of the solder ball 16 and still further be more excellent in reliability.

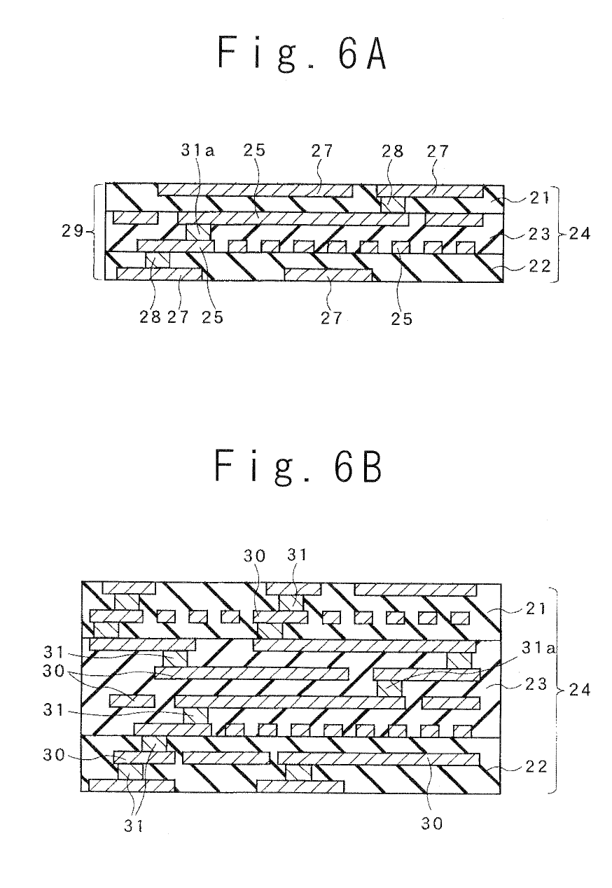

Next, wiring boards for mounting semiconductor device according to a third exemplary embodiment of the present invention will be described. FIGS. 6A and 6B are cross-sectional views showing the wiring boards for mounting semiconductor device according to the present exemplary embodiment. As shown in FIG. 6A, a wiring board for mounting semiconductor device, 29 according to the present exemplary embodiment includes a dielectric film 24. The dielectric film 24 includes at least, a first dielectric layer 21 at the front surface, a second dielectric layer 22 at the back surface, and a third dielectric layer 23 therebetween. The wiring board for mounting semiconductor device, 29 includes wirings 25 buried at the front and back surfaces of the third dielectric layer 23, and a via 31a for electrically connecting the wirings 25. The wiring board for mounting the semiconductor, 29 also includes electrode pads 27 provided at the front and back surfaces of the dielectric film 24 with their surfaces exposed and at least portions of the lateral sides of them buried into the dielectric film 24. The electrode pad 27 and the wiring 25 are electrically connected through a via 28. The via 31a is filled with material different from the case of the via 28, which for example, is conductive paste or solder paste. As describe above, the electrode pad 27 can be any of an electrode pad buried into the dielectric film 24 such that the exposed surface of the electrode pad is arranged at the same level as the front surface or the back surface of the dielectric film 24 as shown in FIG. 2A, an electrode pad buried into the dielectric film 24 such that the exposed surface of the electrode pad is depressed from the front surface or the back surface of the dielectric film 24 as shown in FIG. 2B, and an electrode pad buried into the dielectric film 24 such that the exposed surface of the electrode pad protrudes from the front surface or the back surface of the dielectric film 24 as shown in FIG. 2C.

A conventional wiring board has a structure in which wirings are provided on the front and back surfaces of a dielectric layer arranged inside. Therefore, when the wiring board is formed by stacking dielectric layers formed of different material from the case of the dielectric layer arranged inside, stress to strip the interface of the dielectric layers from each other is caused due to the difference in thermal expansion coefficient and so forth as a result of a heat load caused by the operation of a semiconductor device, and stripping at the interface of dielectric layers may develop from a wiring end at which adhesion is weak due to the structure. On the other hand, the wiring board for mounting semiconductor device, 29 according to the present invention has a structure that the wirings 25 are buried at the front and back surfaces of the third dielectric layer 23 arranged inside. Therefore, even when the first dielectric layer 21 and the second dielectric layer 22 are formed of material different from the case of the third dielectric layer 23 to form the dielectric film 24, stripping at the interface of dielectric layers with a wiring end as the starting point can completely be prevented since stripping stress caused by repeated application of a heat load and bias due to the operation of a semiconductor device are received by the whole surface of the third dielectric layer 23.

Therefore, concerning the wiring board for mounting semiconductor device, 29 according to the present exemplary embodiment, materials of desired physical properties in accordance with purposes are selected for the first dielectric layer 21 at the front surface, the second dielectric layer 22 at the back surface and the third dielectric layer 23 inside. Consequently, it is possible to solve problems that since material of a board is limited to a single kind, which is thermoplastic polyimide, as disclosed in Japanese Laid Open Patent Application (JP-P2004-228165A), reliability may be deteriorated depending on parts to be mounted, that the material cost is high, and that the electricity cost for heating is high because high temperature is required for sticking.

The wiring board for mounting semiconductor device, 29 according to the present exemplary embodiment can have a multilayer wiring structure as shown in FIG. 6B. A wiring 30 and a via 31 are provided in each of the first dielectric layer 21 arranged at the front surface of the dielectric film 24 and the second dielectric layer 22 arranged at the back surface of the dielectric film 24. A wiring 30 and a via hole are provided in the third dielectric layer 23 arranged inside the dielectric film 24. As for the third dielectric layer 23, a via of at least one layer or more among vias between wirings is a via 31a filled with material, such as conductive paste or solder paste, different from the case of the via 31.

Furthermore, the wiring board assembly 14 and 20 can be formed in the same way as in the case of the above-mentioned wiring board for mounting semiconductor device, 5 even by using the wiring board for mounting semiconductor device, 29 according to the present exemplary embodiment. When semiconductor devices are mounted on both sides of the wiring board for mounting semiconductor device, 29, for example, a rigid material with high elastic modulus is selected for the third dielectric layer 23 for the purpose of improving handling, and the same material but with higher film strength or lower thermal expansion coefficient than the case of the third dielectric layer 23 is applied to the first dielectric layer 21 and the second dielectric layer 22. Thus, it is prevented that cracks occur from the surface of the wiring board for mounting semiconductor device, 29 due to difference in thermal expansion coefficients during mounting semiconductor devices When a semiconductor device is mounted on the side of the first dielectric layer 21 of the wiring board for mounting semiconductor device, 29, not only a semiconductor device but also a solder ball are provided on the side of the second dielectric layer 22 of the wiring board for mounting semiconductor device, 29 and the wiring board for mounting semiconductor device, 29 is mounted on a motherboard; different materials are applied to all the dielectric layers, and thus the wiring board for mounting semiconductor device, 29 is formed with optimized reliability. For example, a rigid material with high elastic modulus is selected for the third dielectric layer 23 for the purpose of improving handling, a material with higher film strength or lower thermal expansion coefficient than the case of the third dielectric layer 23 is applied to the first dielectric layer 21 and a material with lower elastic modulus than the case of the third dielectric layer 23 is applied to the second dielectric layer 22.

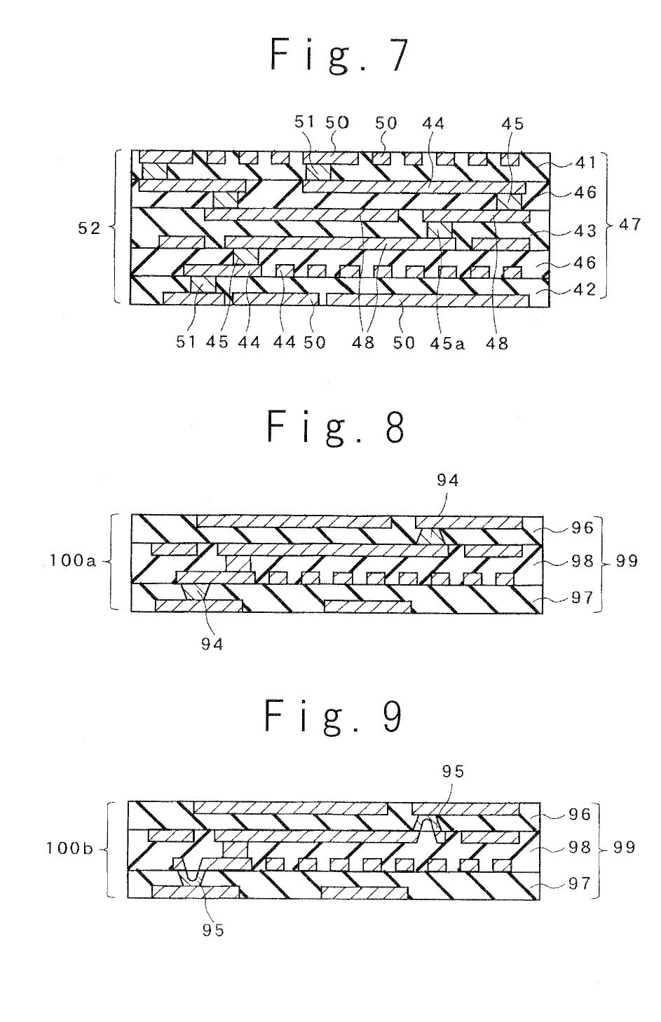

Next, a fourth exemplary embodiment of the present invention will be described. FIG. 7 is a cross-sectional view showing a wiring board for mounting semiconductor device according to the present exemplary embodiment. The wiring board for mounting semiconductor device, 52 according to the present exemplary embodiment includes a dielectric film 47. The dielectric film 47 includes a first dielectric layer 41 positioned at the front surface, a second dielectric layer 42 positioned at the back surface, a third dielectric layer 43 positioned inside, and a fourth dielectric layer 46 provided at least one of between the first dielectric layer 41 and the third dielectric layer 43 and between the second dielectric layer 42 and the third dielectric layer 43. A wiring 44 and a via 45 are formed in the fourth dielectric layer 46. Wirings 48 are buried at the front and back surfaces of the third dielectric layer 43 and a via 45a filled with material different from the case of the via 45, e.g. conductive paste or solder paste, is formed in the third dielectric layer 43 as a via for electrically connecting the wirings 48. In addition, electrode pads 50 each with the surface being exposed and at least portion of the lateral side being buried into the dielectric film 47 are formed in the front and back surfaces of the dielectric film 47. The electrode pad 50 and the wiring 44 are electrically connected through a via 51.

The wiring board for mounting semiconductor device, 52 according to the present invention has a structure in which the wirings 48 are buried at the front and back surfaces of the third dielectric layer 43 positioned inside and the wiring 44 is buried into the fourth dielectric layer 46. For this reason, even when the dielectric film 47 is formed by applying different materials to all the dielectric layers, stripping at the interface of the dielectric layers with a wiring end as the starting point can completely be prevented since stripping stress caused by repeated application of a heat load and bias due to the operation of a semiconductor device are received by the whole surfaces of the third dielectric layer 43 and the forth dielectric layer 46.

It is possible to form the wiring board assembly 14 and the wiring board assembly 20 by using the wiring board for mounting semiconductor device, 52 according to the present exemplary embodiment in the same way as the above-mentioned wiring board for mounting semiconductor device, 5 and the wiring board for mounting semiconductor device, 29. Here, when semiconductor devices are mounted on both sides of the wiring board for mounting semiconductor device, 52, it is preferable to select a material with high elastic modulus for the third dielectric layer 43 for the purpose of improving handling, apply, for example, a material with lower elastic modulus to the forth dielectric layer 46 for the purpose of stress relaxation and apply a material with higher film strength or lower thermal expansion coefficient than the cases of the third dielectric layer 43 and the forth dielectric layer 46 to the first dielectric layer 41 and the second dielectric layer 42. As a result, it is possible to prevent occurrence of cracks from the surface of the wiring board for mounting semiconductor device, 52 due to difference in thermal expansion coefficient during mounting a semiconductor device and form the wiring board for mounting semiconductor device, 52 having a stress relaxation function. For this reason, it is possible to form a circuit board with high reliability as a wiring board assembly, compared with the board obtained by the method disclosed in Japanese Laid Open Patent Application (JP-P2003-60348A).

Additionally, when a semiconductor device is mounted on the side of the first dielectric layer 41 of the wiring board for mounting semiconductor device, 52, not only a semiconductor device but also a solder ball are provided on the side of the second dielectric layer 42 of the wiring board for mounting semiconductor device, 52 and the wiring board for mounting semiconductor device, 52 is mounted on a motherboard; different materials are applied to all the dielectric layers and the wiring board for mounting semiconductor device, 52 is formed with optimized reliability. For example, a rigid material with high elastic modulus is selected for the third dielectric layer 23 for the purpose of improving handling, a material with lower thermal expansion coefficient is applied to the forth dielectric layer 42, a material with higher film strength than the cases of the third dielectric layer 43 and the forth dielectric layer 46 is applied to the first dielectric layer 41 and a material with lower elastic modulus than the cases of the third dielectric layer 43 and the forth dielectric layer 46 is applied to the second dielectric layer 43.

Next, a fifth exemplary embodiment of the present invention will be described. FIG. 8 is a cross-sectional view showing a wiring board for mounting semiconductor device according to the present exemplary embodiment. The wiring board for mounting semiconductor device, 100a according to the present exemplary embodiment includes a dielectric film 99. The dielectric film 99 includes a first dielectric layer 96 positioned at the front surface, a second dielectric layer 97 positioned at the back surface, and a third dielectric layer 98 positioned inside. The wiring board for mounting semiconductor device, 100a has a structure in which the size of the front surface side (upper side in the figure) of a via 94 formed in the first dielectric layer 96 is smaller than the size of the back surface side (lower side in the figure) thereof and the size of the back surface side (lower side in the figure) of a via 94 formed in the first dielectric layer 96 is smaller than the size of the front surface side (upper side in the figure) thereof. Such shapes of the vias can be achieved by via formation using laser processing or a photo via using photosensitive resin, for example. Generally, the sizes of via are different between the incident side and the other side of a laser beam of laser processing or exposure light of exposure process. As a result, it is possible to obtain the wiring board for mounting semiconductor device 100a having the vias, in which the size of the front surface side (the upper side in the figure) of the via 94 formed in the first dielectric layer 96 is smaller than the size of the back surface side (the lower side in the figure) thereof and the size of the back surface side (the lower side in the figure) of the via formed in the second dielectric layer 97 is smaller than the size of the front surface side (the upper side in the diagram) thereof, and form a board to which semiconductor devices are connected in high density.

Additionally, when the shape of via is a circular truncated cone, the above-mentioned via size denotes the diameter at the upper portion or the lower portion of the via. The shape of via is not a circular shape in some case, and in this case, an appropriate value such as perimeter can be defined as the size.

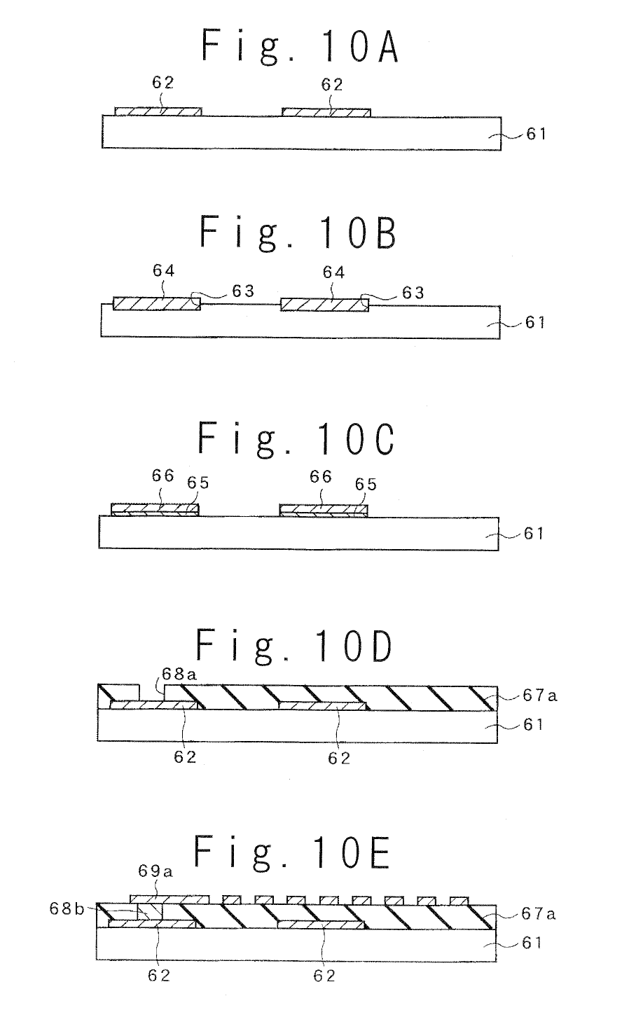

Next, a sixth exemplary embodiment of the present invention will be described. FIG. 9 is a cross-sectional view showing a wiring board for mounting semiconductor device 100b according to the present exemplary embodiment. The structure according to the present exemplary embodiment is different from that of the above-mentioned wiring board for mounting semiconductor device, 100a in that vias formed in the first dielectric layer 96 and the second dielectric layer 97 are not the filled vias 94 but conformal vias 95 and is the same for the rest. In the case of the filled vias 94, there is an advantage to increase wiring density since a wiring can be arranged on the via, and wiring and pad can be designed such that the filled vias 94 are stacked. In the case of the conformal via 95 on the other hand, there is an advantage that reliability characteristics such as temperature cycle is improved since the via has the effect of stress relaxation.

Additionally, the relationship between the size of the front surface side of the via and the size of the back surface side thereof may be the opposite relationship shown in FIG. 8 and FIG. 9.

Because the via is different in sizes at the front surface side and at the back surface side as mentioned above, wiring densities at both sides of the via can be different each other. At this time, it is desirable that the size at the side in which high wiring density is required be smaller. In the case of a laser via formed by using laser and a photo via formed by using light, a via diameter at the side of incidence of laser and light tends to be larger in general. Therefore, the relationships between the size of the front surface side and the size of the back surface side can be controlled to be the opposite relationships by making an incident direction of laser beam or light for the formation in the first dielectric layer 96 opposite to an incident direction of laser beam or light for the formation in the second dielectric layer 97.

Furthermore, it is desirable that via sizes at the front surface side and the back surface side for mounting semiconductor elements be small, since as for high-performance semiconductor elements, intervals between pads as connecting portions to a wiring board are extremely narrow and expected to be further narrower in future. The wiring board for mounting semiconductor device according to the present invention can mount semiconductor elements on both sides, and thus it is especially desirable that the front-surface-side size of the via formed in the first dielectric layer 96 should be smaller than the back-surface-side size and the back-surface-side size of the via formed in the second dielectric layer 97 should be smaller than the front-surface-side size.

Next, a manufacturing method of a wiring board for mounting semiconductor device according to the present invention will be described. FIGS. 10A to 10E and FIGS. 11A to 11D are cross-sectional views in the order of process illustrating the manufacturing method of the wiring board for mounting semiconductor device according to the first exemplary embodiment of the present invention. As shown in FIG. 10A, a conductive layer to be electrode pads 62 is firstly formed on a supporting base 61 using a plating method or the like. Here, it is also possible as shown in FIG. 10B, to form electrode pads 64 which are partly buried in the supporting base 61 by forming concave portions 63 on the supporting base 61 in advance by etching and forming the conductive layer to be buried therein. Alternatively, it is also possible as shown in FIG. 10C, to form electrode pads 66 each having a two-layered structure of a barrier layer 65 and a conductive layer by providing the barrier layer 65 on the supporting base 61 first and forming the conductive layer on the barrier layer 65 next.

Next, as shown in FIG. 10D, a dielectric layer 67a is formed on the supporting base 61 with the electrode pads 62, 64 or 66 formed as mentioned above, and a via hole 68a is formed in the dielectric layer 67a. After that, a wiring 69a is formed on the dielectric layer 67a by a plating method, as shown in FIG. 10E. As a result, conductive material for the wiring is buried into the via hole 68a to form a via 68b which connects the electrode pad and the wiring.

Next, as shown in FIG. 11A, a dielectric layer 67b is formed on the wiring 69a and a via hole is formed in the dielectric layer 67b in the same way as the method of forming the via hole 68a. A via 68c is filled with conductive material such as conductive paste or solder paste by forming a wiring 69b with the conductive material such as conductive paste or solder paste on the dielectric layer 67b. Next, as shown in FIG. 11B, a wiring board with supporting base, 73 provided with the dielectric layer 67b and the via 68c on the wiring 69a is formed by polishing and removing the wiring 69b as the uppermost layer to be removed. The via 68c can also be formed by filling conductive material such as conductive paste or solder paste into the via hole in the dielectric layer 67b.

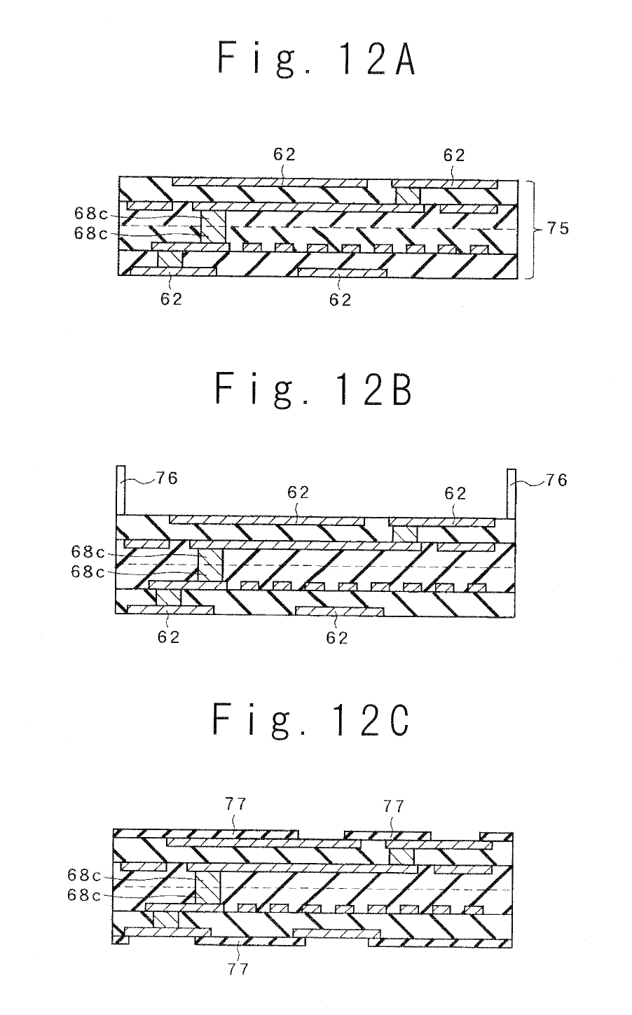

Next, as shown in FIG. 11C, the wiring board with supporting base, 73 are piled such that the dielectric layers 67b contact each other, are in face-to-face such that the vias 68c exposed at the surfaces of the dielectric layers 67b contact each other, and then, are stuck together. After that, both the supporting bases 61 are entirely removed by etching or the like to form a wiring board for mounting semiconductor device, 75 as the wiring board for mounting semiconductor device according to the first exemplary embodiment of the present invention, which has the electrode pads 62 exposed at both the front and back surfaces and a multilayer wiring structure inside, as shown in FIG. 12A.

Alternatively, as shown in FIG. 11D, the wiring board for mounting semiconductor device according to the first exemplary embodiment of the present invention can also be formed by sticking the board before the dielectric layer 67b and the via 68b are formed as shown in FIG. 10E and the wiring board with supporting base, 73 together and entirely removing both the supporting bases 61 by etching or the like thereafter.

According to the present invention, fine pitch between vias can be maintained by forming the via 68b using a plating method. Furthermore, by filling the vias 68c to contact each other, namely the vias to be stuck together, with adhesive material, e.g. conductive paste or solder paste, adhesion between the vias can be improved. According to the present invention therefore, it is possible to provide a high-density and highly-reliable wiring board. In particular, when using conductive paste or solder paste containing metal powder particles, metal joining between the powder particles is formed, and thus the vias adhere together strongly.

Alternatively, as shown in FIG. 12B, the wiring board for mounting semiconductor device, 75 provided with a supporting body 76 can be obtained by leaving partly the supporting base 61 to form the supporting body 76. Furthermore, as shown in FIG. 12C, a solder resist 77 can be formed to any place on both sides of the wiring board for mounting semiconductor device, 75 when necessary.

Alternatively, as shown in FIG. 11A, the number of the layers can be increased by forming the dielectric layer 67b on the wiring 69a, forming in the dielectric layer a via hole in the same way as the method of forming the via hole 68a, and forming the via 68c by forming the wiring 69b on the dielectric layer 67b thereafter. By repeating this process, the number of the layers can be increased to the desired number.

Although there is no specific limitation on the material of the supporting base 61, a material superior in workability is preferable when considering that the supporting base 61 is removed finally. As a specific example for the supporting base 61, metal such as copper, copper alloy, stainless steel or aluminum, or material such as glass or silicon is preferable.

For instance, when the supporting base is a metal supporting base including a thin-film metal layer and a supporting metal layer thicker than the thin-film metal layer, only the thicker supporting metal layer can be stripped while leaving only the thin-film metal layer on the board when removing the supporting base. As a result, the metal layer required to be removed later by etching or the like, is very thin.

It is also possible when forming an opening to the dielectric layer with laser or the like, to form the opening with laser in the state of the above-mentioned thin-film metal layer being left and perform desmear process or the like thereafter. In this method, since the other portions other than the via opening are covered with the thin-film metal layer during the desmear process, there is no damage to resin due to desmear solution or the like and the contamination of the desmear solution can be reduced.

It is preferable that the conductor materials formed of conductive paste or solder paste provided in the vias 68c certainly fuse to be connected by heating and pressing when the wiring boards with supporting base, 73 are stuck together. More in detail, conductive paste in which metal particles are dispersed in resin, solder or the like is preferable. Additionally, the dielectric layers 67a and 67b are required to be heat resistant and chemical resistant in the manufacturing process. When there is no problem in this respect, any material can be selected for the dielectric layers 67a and 67b.

In the manufacturing method of the wiring board for mounting semiconductor device according to the first exemplary embodiment of the present invention mentioned above, as shown in FIG. 11C, the wiring boards with supporting base, 73, in each of which the dielectric layer and the wiring are formed on the supporting base 61 with high dimensional stability, are stuck together face to face. Therefore, the high-density and high-accuracy wiring board for mounting semiconductor device, 75 with good accuracy in the positions of the electrode pads 62 can be obtained as shown in FIG. 12A.

Furthermore, since both surfaces to be stuck together face to face are flattened by forming the dielectric layer 67b on the wiring 69a, the dielectric layer 67b is not required to be deformed by heating and pressing for the sticking, an uniform load distribution is possible in the pressing regardless of the arrangement of the vias, and both the surfaces can be stuck together at extremely low temperature and week pressing force. For this reason, no distortion occurs in the whole wiring board with supporting base, 73 when sticking. Therefore, it is possible to obtain the highly-reliable wiring board for mounting semiconductor device, 75 with less damage to the wirings and the dielectric layers. Furthermore, it is also possible to form the circuit board with excellent flatness after removing the supporting base such as copper plate after the pressing, since rigid resin including aramid cloth, glass cloth or the like is used as the adhesion layer for the sticking. This makes it possible to cut the process of forming a dielectric layer for the purpose of flatness required in the method disclosed in Japanese Laid Open Patent Application (JP-P2003-188536A), and reduce the interface between different materials, which may cause a failure, since this dielectric layer is not present.

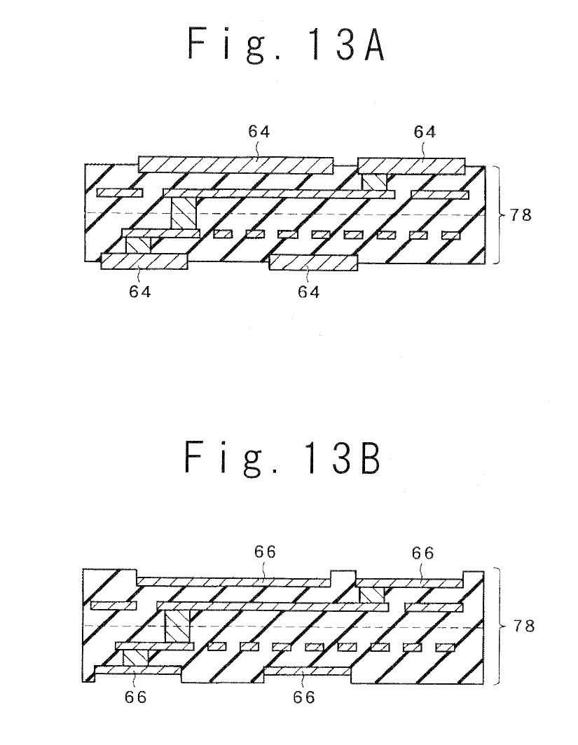

In addition, when the concave portions 63 are formed in advance to the supporting base 61 through etching and the electrode pads 64 are formed by burying the conductive layer into the concave portions 63 as shown in FIG. 10B, a wiring board for mounting semiconductor device with the exposed surfaces of the electrode pads 64 protruding from the front surface or the back surface of the dielectric film 78 can be obtained as shown in FIG. 13A by removing the supporting base 61 entirely or partially.

On the other hand, when the barrier layer 65 is provided in advance on the supporting base 61 and the conductive layer is stacked on the barrier layer 65 to form the electrode pad 66 as shown in FIG. 10C, a wiring board for mounting semiconductor device with the exposed surfaces of the electrode pads 66 depressed from the front surface or the back surface of the dielectric film 78 can be obtained, as shown in FIG. 13B, by removing the supporting base 61 entirely or partially and further removing the barrier layer 65.

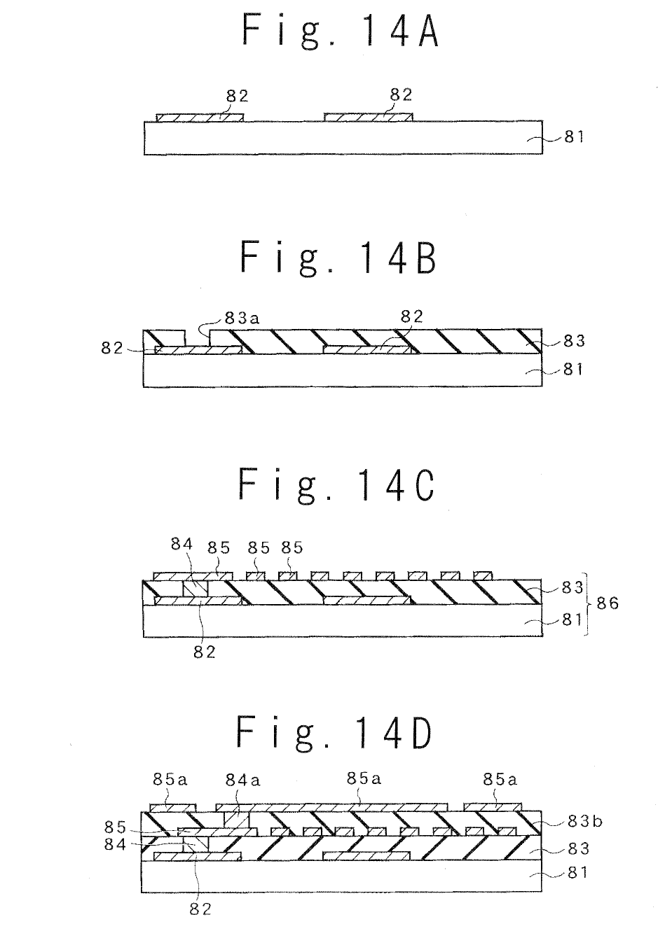

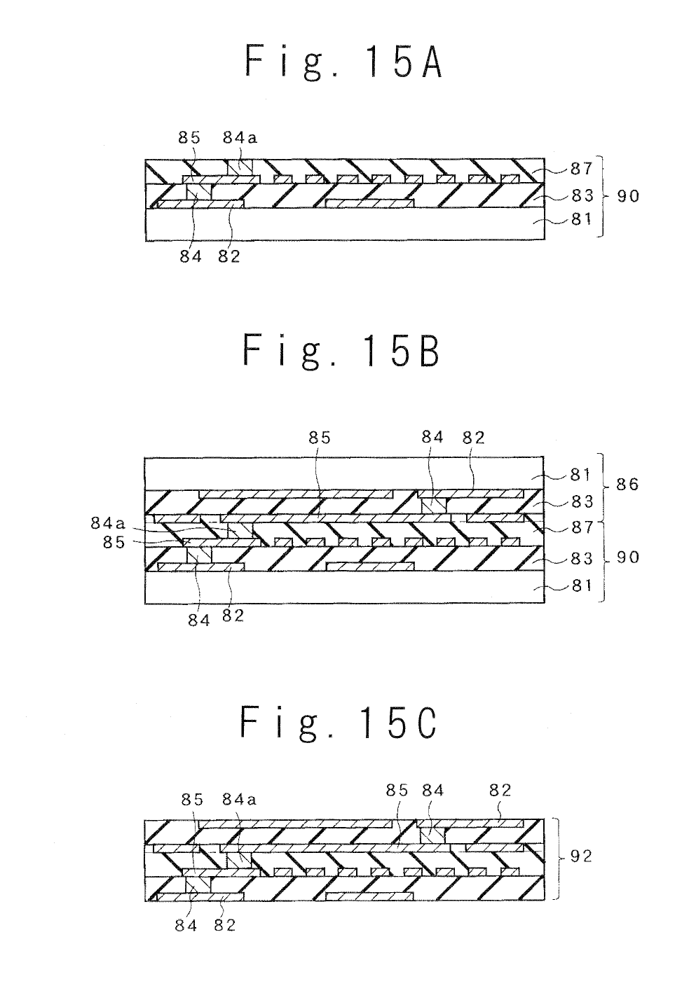

Next, another manufacturing method of the wiring board for mounting semiconductor device according to the present invention will be described. FIGS. 14A to 14D and FIGS. 15A to 15C are cross-sectional views in the order of process illustrating the manufacturing method of the wiring board for mounting semiconductor device according to the first exemplary embodiment of the present invention. First, as shown in FIG. 14A, an electrode pad 82 is formed on a supporting base 81 by patterning a conductive layer. Alternatively, it is also possible to form an electrode pad with an exposed surface protruding from the front surface or the back surface of a dielectric film by forming the conductive layer buried in a concave portion formed in advance on the supporting base 81 through etching as described above and finally removing the supporting base 81 entirely or partially as described later. Furthermore, it is also possible to form an electrode pad with an exposed surface depressed from the front surface or the back surface of a dielectric film by providing a barrier layer in advance on the supporting base 81, forming the conductive layer to be the electrode pad 82, removing the supporting base 81 entirely or partially and removing the barrier layer. The case will be described below that the electrode pad 82 is formed on the supporting base 81 as shown in FIG. 14A.

Next, a dielectric layer 83 is formed on the supporting base 81 as shown in FIG. 14B. Furthermore, a via hole 83a that reaches the electrode pad 82 is formed to the dielectric layer 83.

Next, a wiring 85 is formed on the dielectric layer 83 as shown in FIG. 14C. At this time, conductive material for the wiring 85 is also buried into the via hole 83a and a via 84 which connects the wiring 85 and the electrode pad 82 is formed. As a result, a wiring board with supporting base, 86 is obtained.

If necessary, as shown in FIG. 14D, a dielectric layer 83b is formed on the wiring 85 and the dielectric layer 83, a wiring 85a is formed on the dielectric layer 83b, and a via 84a is formed in the dielectric layer 83b. By repeating such process of forming a dielectric layer, a wiring, and a via, the wiring board with supporting base, 86 which has multilayered wirings is obtained.

Next, as shown in FIG. 15A, a dielectric layer 87 is formed on a supporting base 86 and the wiring 85 shown in FIG. 14C. A via hole is formed inside the dielectric layer 87 and a via 84a is formed by burying conductive material such as conductive paste or solder paste into the via hole.

As a result, a wiring board with supporting base, 90 having the via 84a is obtained.

Next, as shown in FIG. 15B, the wiring board with supporting base, 86 shown in FIG. 14C and the wiring board with supporting base, 90 having the via 84a filled with conductive paste or solder paste as shown in FIG. 15A are stuck together face to face.

Finally, as shown in FIG. 15C, the wiring board for mounting semiconductor device, 92 according to the first exemplary embodiment of the present invention is obtained by removing the whole supporting base 81 to expose the electrode pad 82.

If necessary, as shown in FIG. 12B, it is also possible to form the wiring board for mounting semiconductor device, 92 to have a supporting body (supporting body 76) by removing the supporting base 81 not entirely but partially to leave a portion of the supporting base as the supporting body. Furthermore, as shown in FIG. 12C, it is also possible to form a solder resist (solder resist 77) to any place of both sides of the wiring board for mounting semiconductor device, 92.

According to the above-mentioned manufacturing method of the wiring board for mounting semiconductor device according to the first exemplary embodiment of the present invention, since the surface of the wiring board with supporting base, 86 is not flat, accuracy is not so good in the sticking. However, this manufacturing method has advantages that the manufacturing process is shortened and cost down is achieved since it is enough to form the dielectric layer 87 to only one of the wiring boards with supporting base, 90 to be stuck together face to face and the via 84a filled with conductive paste or solder paste in the dielectric layer 87.

However, the property of the dielectric layer 87 is important to stick face to face the wiring board with supporting base, 86 to the wiring board with supporting base, 90 having the via 84a filled with conductive paste or solder paste under the appropriate conditions of low temperature and low pressure. It is preferable that thermosetting resin which is lower than the dielectric layer 83 in curing temperature and easily flows by heating and pressing in the stacking is applied to dielectric layer. More specifically, epoxy resin and modified polyimide are raised as examples and epoxy resin including elastomer components is preferable. By applying these materials to the dielectric layer 87, a low-cost wiring board for mounting semiconductor device, 92 having high reliability is obtained.

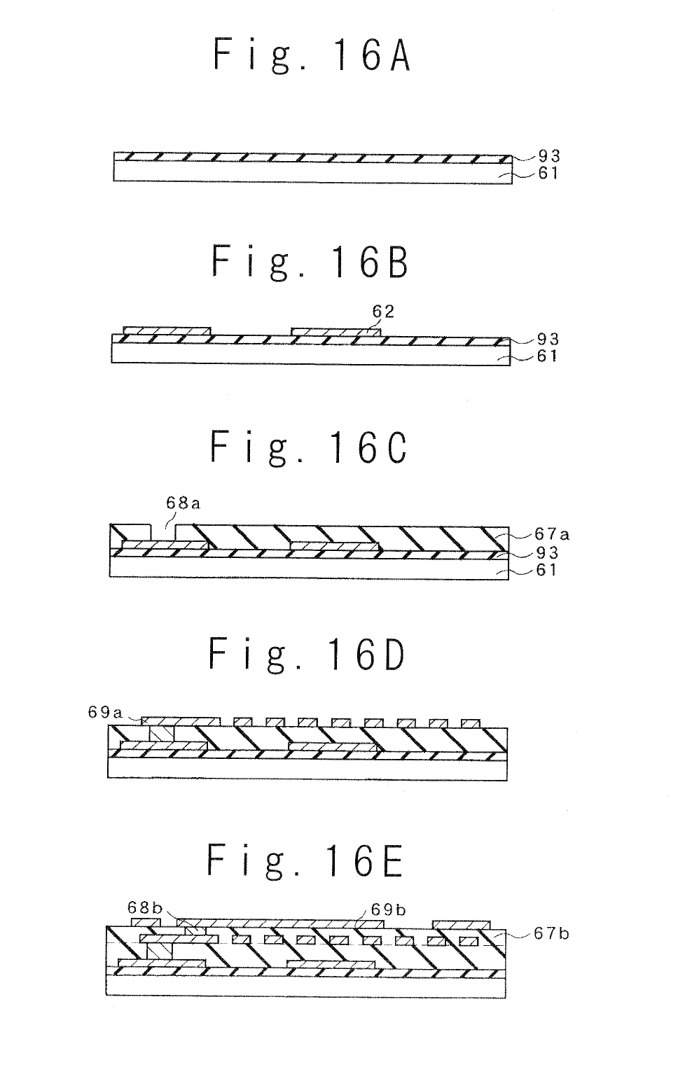

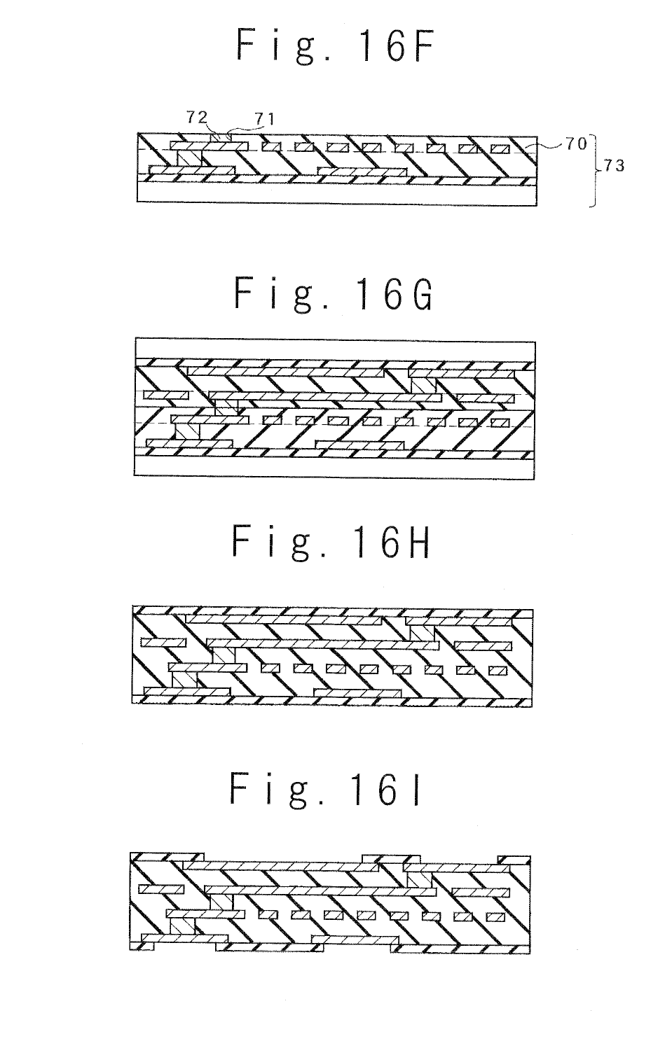

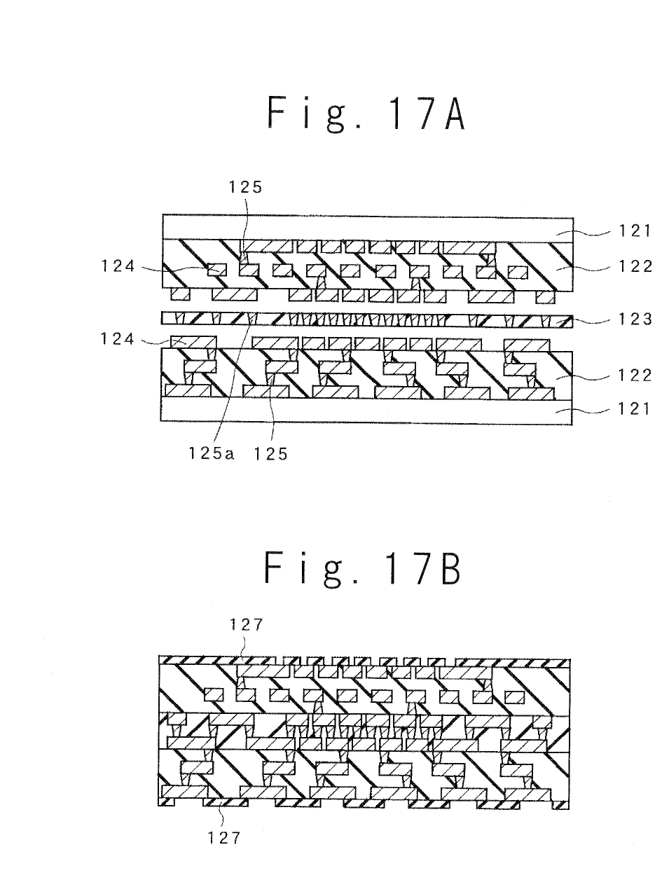

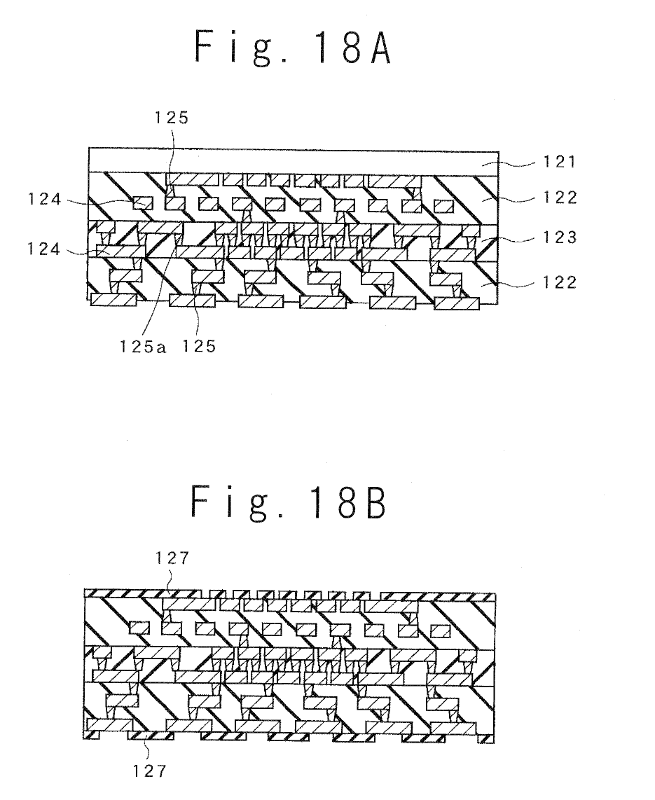

Next, still another manufacturing method of the wiring board for mounting semiconductor device according to the present invention will be described. FIGS. 16A to 16I are cross-sectional views in the order of process illustrating the manufacturing method of the wiring board for mounting semiconductor device according to the first exemplary embodiment of the present invention. In this manufacturing method, a dielectric layer 93 is firstly formed on the supporting base 61 as shown in FIG. 16A, and a conductive layer to be the electrode pad 62 is formed thereon. Wiring layers and so forth are subsequently formed in the same way as the example of FIG. 7, two board are stuck together, and the supporting base 61 is removed thereafter (FIG. 16H). An opening to expose the pad is formed to the dielectric layer 93 which was firstly formed on the supporting base 61 (FIG. 16I). The opening is preferably formed by using laser or dry etching especially in terms of ease and accuracy in position, however, the forming method of the opening is not limited to those. In FIGS. 16A to 16I, numerals 67a, 67b, and 70 denote dielectric layers, numerals 68a, 68b and 71 denote vias, numerals 69a and 69b denote wirings, numeral 72 denotes a conductor, and numeral 73 denotes a wiring board with supporting base.

Since the dielectric layer 93 is firstly formed on the supporting base 61 and the metal layer such as the pad is formed thereafter in the manufacturing method, the dielectric layer 93 on the supporting base 61 serves as a strong etching barrier layer. For this reason, a pad section and a wiring section are less likely to be damaged by etching solution during the etching the copper plate, and a reliable board for a wiring board assembly is obtained. Additionally, the dielectric layer 93 after the formation of the opening serves as a solder resist. The dielectric layer 93 after the formation of the opening is superior in adhesion with metals forming the pad and the wiring compared with a solder resist formed after etching the supporting body, and thus serves as a stable solder resist layer. Furthermore, the opening can be formed above the pad at high accuracy in position since the opening can be formed above the pad after checking the position of the pad.

Next, still another manufacturing method of the wiring board for mounting semiconductor device according to the present invention will be described. FIGS. 17A to 17B are cross-sectional views in the order of process illustrating the manufacturing method of the wiring board for mounting semiconductor device according to the first exemplary embodiment of the present invention. As shown in FIG. 17A, a via hole is formed in advance to a resin sheet 123 as a third dielectric layer, using laser, a drill, development by exposure, or other method. A via 125a is formed by filling the via hole with conductive paste or solder paste using a printing method, a ink-jet method or other method. After that, boards each with a supporting plate 121 and each having a wiring 124 and a via 125 based on an arbitrary design formed in a forth dielectric layer 122 mainly by a plating method are arranged such that the opposite sides of the boards to the supporting plates 121 face to each other with the third dielectric layer sheet 123 therebetween. After alignment is performed such that the via 125a filled with conductive paste or solder paste is connected to proper electrode wiring, the boards are stuck together through the third dielectric layer sheet 123 by vacuum pressing or the like.

In the following process, the supporting plates 121 formed at both sides are removed by etching or by applying stress, heat, ultraviolet rays or the like, as shown in FIG. 17B. Furthermore, by forming as first and second dielectric layers, solder resists 127 in each of which openings are formed at positions corresponding to electrodes as shown in FIG. 17B, workability in mounting and surface mounting of semiconductor elements thereafter can be improved.

In order to form the via hole to the resin sheet 123 as the third dielectric layer, it is possible to use a method using a drill, a formation method using development by exposure, a formation method using laser, and so forth. In the case of the formation using the drill, the third dielectric layer 123 does not cure before the pressing for sticking since heat is not applied to the resin sheet. Therefore, since almost all portions of the resin sheet cure for the first time in the sticking, there is an advantage that stronger adhesion can be achieved. When the via hole is formed using development by exposure, there is an advantage that accuracies in the shape and the position of the via can be improved. When using laser, there is an advantage that formation of a smaller via is possible. When using the drill or laser, photosensitive resin with poor mechanical properties does not need to be used to the substrate to be the adhesion layer, and the material can be selected by attaching importance to mechanical strength. As a result, it is possible to form a board with higher reliability than a board with a via hole which is formed using development by exposure in the manufacturing process.

In FIG. 18A, one of boards to be stuck is a board with the supporting plate 121 and the other of the boards to be stuck is a board without supporting plate, which is different from the case of FIG. 17A. In the board with the supporting plate 121, the wiring 124 and the via 125 based on an arbitrary design are formed in the forth dielectric layer 122 mainly by a plating method. The third dielectric layer 123 is formed on the uppermost layer at least one of the board with the supporting plate 121 and the board without supporting plate. A via hole is formed to the dielectric sheet 123, using laser, a drill, development by exposure, or other method, and a via 125a is formed by filling the via hole with conductive paste or solder paste using a printing method, a ink-jet method or other method. Alternatively, a via hole is formed in advance to the resin sheet 123 as the third dielectric layer, using laser, a drill, development by exposure, or other method, and a via 125a is formed by filling the via hole with conductive paste or solder paste using a printing method, a ink-jet method or other method. After that, the board with the supporting plate 121 and the other board without supporting plate are stuck together. As a result, sticking to conventional build-up board and printed board is possible with uniform heating and uniform load distribution by using the board with the supporting plate 121.

After that, as shown in FIG. 18B, the supporting plate 121 is removed by etching or by applying stress, heat, ultraviolet rays or the like. Furthermore, by forming solder resists 127 in each of which openings are formed at positions corresponding to electrodes as shown in FIG. 18B, as first and second dielectric layers, workability in mounting and surface mounting of semiconductor elements thereafter can be improved.

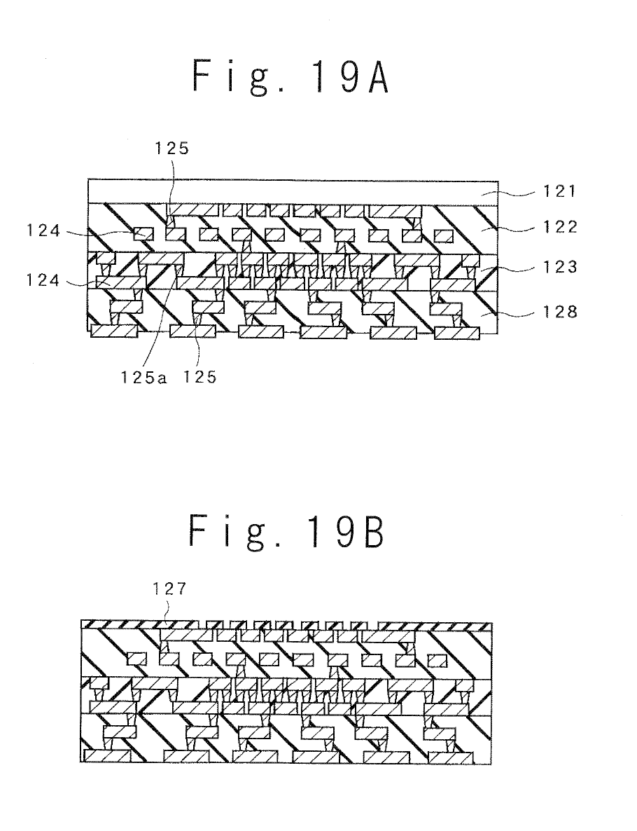

In FIG. 19A, one of boards to be stuck together is the board with the supporting plate 121 and the other of the boards to be stuck is an inorganic board without supporting plate. In the board with the supporting plate 121, the wiring 124 and the via 125 based on an arbitrary design are formed in the forth dielectric layer 122 mainly by a plating method. The third dielectric layer 123 is formed on the uppermost layer at least one of the board with the supporting plate 121 and the board without supporting plate. A via hole is formed to the dielectric sheet 123, using laser, a drill, development by exposure, or other method, and the via 125a is formed by filling the via hole with conductive paste or solder paste using a printing method, an ink-jet method or other method. Alternatively, a via hole is formed in advance to the resin sheet 123 as the third dielectric layer, using laser, a drill, development by exposure, or other method, and the via 125a is formed by filling the via hole with conductive paste or solder paste is formed using a printing method, a ink-jet method or other method. After that, the board with the supporting plate 121 and the inorganic board without supporting plate are stuck together. Here, a fifth dielectric layer 128 to be a substrate of the inorganic board is formed of alumina, silica, silicon or the like, and an LSI wafer may also be used. As a result, sticking to the inorganic board is possible with uniform heating and uniform load distribution by using the board with the supporting plate 121.

After that, as shown in FIG. 19B, the supporting plate 121 is removed by etching or by applying stress, heat, ultraviolet rays or the like. Furthermore, by forming the solder resist 127 in which openings are formed at positions corresponding to electrodes as shown in FIG. 19B, as first or second dielectric layer, workability in mounting and surface mounting of semiconductor elements thereafter can be improved. When sticking to the inorganic substrate in which paste such as an inductor, a capacitor, and a resistor is formed inside the fifth dielectric layer 128, a multifunctional circuit board can be formed.

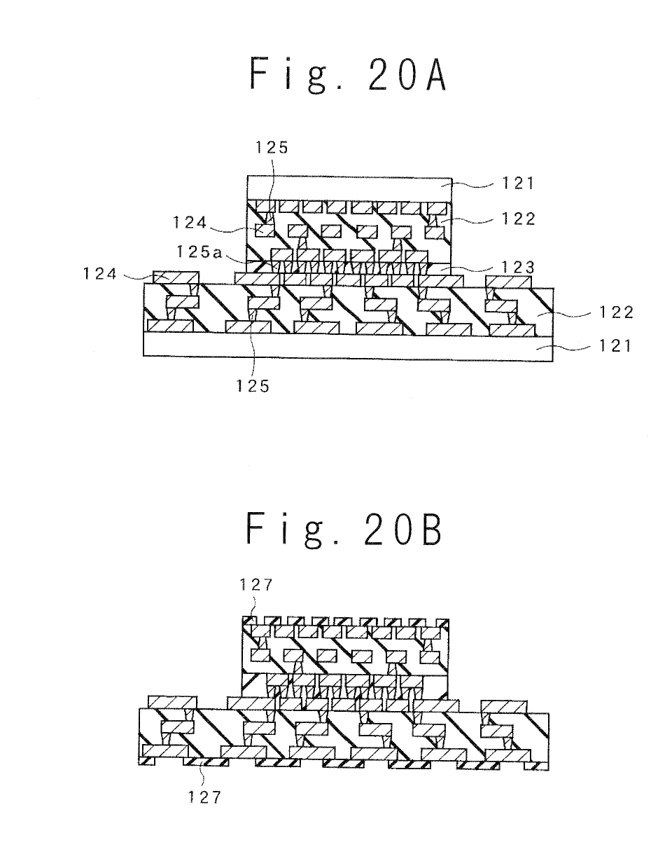

Next, a seventh exemplary embodiment of the present invention will be described. FIGS. 20A and 20B are cross-sectional views showing a wiring board for mounting semiconductor device according to the present exemplary embodiment. The present exemplary embodiment is different from the above-mentioned wiring board for mounting semiconductor device according to the first exemplary embodiment in that external shapes of two boards to be stuck together are different, but has the same structure for the rest.

FIGS. 20A to 20B are cross-sectional views in the order of process illustrating a manufacturing method of the wiring board for mounting semiconductor device according to the present exemplary embodiment. As shown in FIG. 20A, the external shapes of the boards each with supporting plate 121 to be stuck together are different from each other. In the board with the supporting plate 121, the wiring 124 and the via 125 based on an arbitrary design are formed in the forth dielectric layer 122 mainly by a plating method. The third dielectric layer 123 is formed on the uppermost layer at least one of the boards to be stuck together. A via hole is formed to the dielectric sheet 123, using laser, a drill, development by exposure, or other method, and the via 125a is formed by filling the via hole with conductive paste or solder paste using a printing method, an ink-jet method or other method. Alternatively, a via hole is formed in advance to the resin sheet 123 as the third dielectric layer using laser, a drill, development by exposure or other method, and the via 125a is formed by filling the via hole with conductive paste or solder paste using a printing method, an ink-jet method or other method. After that, sticking is performed. As a result, sticking to conventional build-up board and printed board is possible with uniform heating and uniform load distribution by using the board with the supporting plate 121.

After that, the supporting plates 121 are removed by etching or by applying stress, heat, ultraviolet rays or the like, as shown in FIG. 20B. Furthermore, by forming solder resists 127 in each of which openings are formed at positions corresponding to electrodes as shown in FIG. 20B, as first and second dielectric layers, workability in mounting and surface mounting of semiconductor elements thereafter can be improved. Also in the case that the boards with different external shapes are stuck together, by forming the supporting plates 121, a press with uniform temperature and pressure in the sticking surfaces is possible during the sticking, and wirings and dielectric layers are less damaged. As a result, it is possible to obtain a wiring board with higher reliability than a board disclosed in Japanese Laid Open Patent Application (JP-P2004-228165A). In addition, since the boards with different external shapes are stuck together, addition is performed only to a portion in which multilayer wirings are necessary, and thus the volume of the whole board can be reduced. Furthermore, according to this structure, there is area on the dielectric layer on which another dielectric layer with smaller external shape is mounted. The area can effectively be utilized by mounting other semiconductor elements or the like on the area in accordance with purposes, and a high-density wiring board suitable for various purposes can be provided.

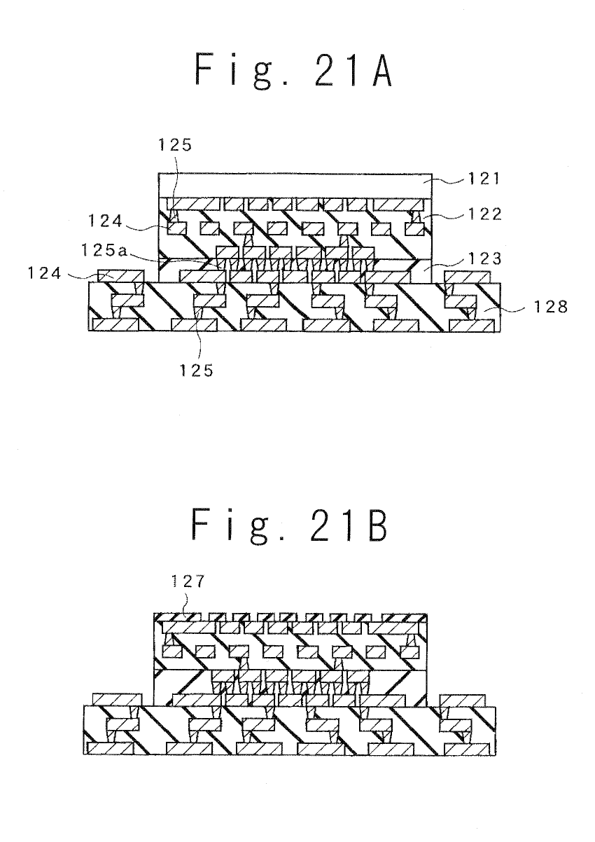

Next, an eighth exemplary embodiment of the present invention will be described. FIGS. 21A and 21B are cross-sectional views showing a wiring board for mounting semiconductor device according to the present exemplary embodiment. As shown in FIG. 21A, a board with the supporting plate 121 and an inorganic board without supporting plate with the external shapes different from each other, are stuck together to form the wiring board for mounting semiconductor device. In the board with the supporting plate 121, the wiring 124 and the via 125 based on an arbitrary design are formed in the forth dielectric layer 122 mainly by a plating method. The third dielectric layer 123 is formed on the uppermost layer of the board with the supporting plate 121 or the inorganic board without supporting plate. A via hole is formed to the dielectric layer 123, using laser, a drill, development by exposure, or other method, and the via 125a is formed by filling the via hole with conductive paste or solder paste using a printing method, a ink-jet method or other method. Alternatively, a via hole is formed in advance to the resin sheet 123 as the third dielectric layer using laser, a drill, development by exposure or other method, and the via 125a is formed by filling the via hole with conductive paste or solder paste using a printing method, an ink-jet method or other method. After that, the wiring board for mounting semiconductor device is formed by sticking the board with the supporting plate 121 and the inorganic board without supporting plate together. Here, the fifth dielectric layer 128 to be the substrate of the inorganic board is formed of alumina, silica, silicon or the like, and an LSI wafer may also be used. As a result, sticking to the inorganic board is possible with uniform heating and uniform load distribution by using the board with the supporting plate 121.

After that, as shown in FIG. 21B, the supporting plate 121 is removed by etching or by applying stress, heat, ultraviolet rays or the like. Furthermore, by forming the solder resist 127 in which openings are formed at positions corresponding to electrodes as shown in FIG. 21B, as first or second dielectric layer, workability in mounting and surface mounting of semiconductor elements thereafter can be improved. When sticking to the inorganic substrate in which paste such as an inductor, a capacitor, and a resistor is formed inside the fifth dielectric layer 128, a multifunctional circuit board can be formed. In addition, since the boards with different external shapes are stuck together, addition is performed only to a portion in which multilayer wirings are necessary, and thus the volume of the whole board can be reduced.

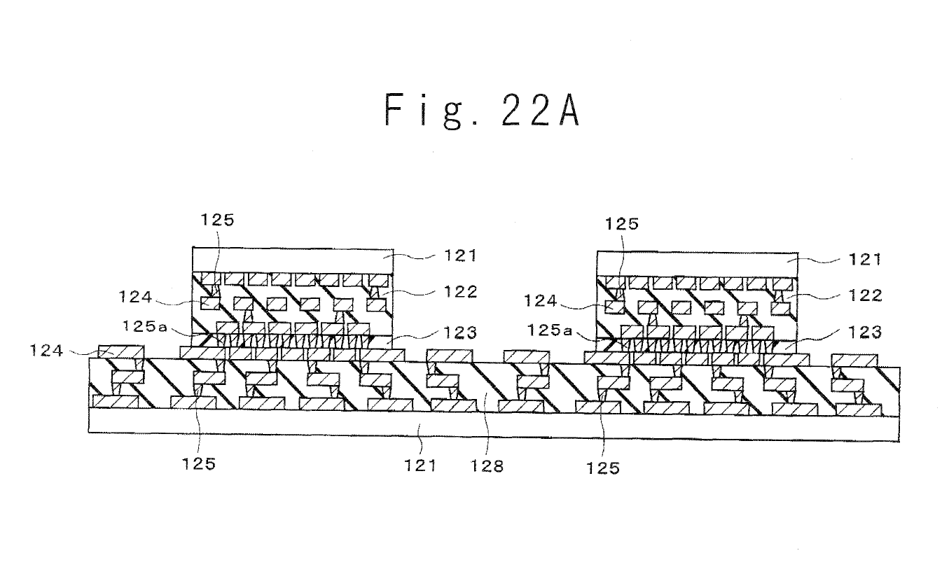

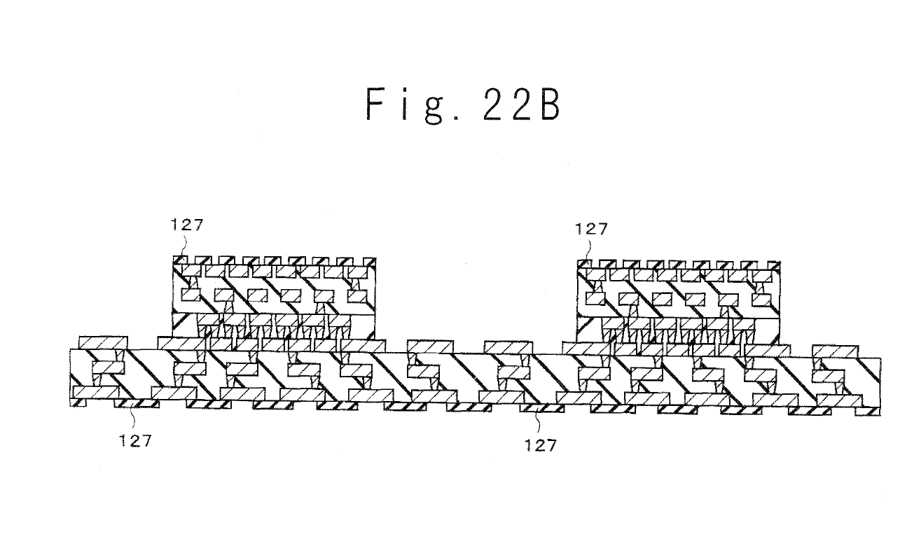

Next, a ninth exemplary embodiment of the present invention will be described. FIGS. 22A and 22B are cross-sectional views showing a wiring board for mounting semiconductor device according to the present exemplary embodiment. The present exemplary embodiment is different from the above-mentioned wiring board for mounting semiconductor device according to the first exemplary embodiment in that the external shapes of the two boards to be stuck together are different and the number of boards connected through the third dielectric layer is different, but has the same structure for the rest.

As shown in FIG. 22A, the boards each with the supporting plate 121, in each of which the wiring 124 and the via 125 based on an arbitrary design are formed in the forth dielectric layer 122 mainly by a plating method are used. The third dielectric layer 123 is formed on the uppermost layer of at least one of the boards to be stuck. A via hole is formed to the dielectric layer 123, using laser, a drill, development by exposure, or other method, and the via 125a is formed by filling the via hole with conductive paste or solder paste using a printing method, a ink-jet method or other method. Alternatively, a via hole is formed in advance to the resin sheet 123 as the third dielectric layer using laser, a drill, development by exposure or other method, and the via 125a is formed by filling the via hole with conductive paste or solder paste using a printing method, an ink-jet method or other method. After that, sticking is performed.

Since there are two or more places to be stuck in this case, when heights of the boards are different, it is also possible to perform a cure of resin in the process after a temporal connection using a flip-chip mounter or the like is performed for each of the places to be stuck. Furthermore, sticking to conventional build-up board and printed board is possible with uniform heating and uniform load distribution by using the board with the supporting plate 121.

After that, as shown in FIG. 22B, the supporting plates 121 are removed by etching or by applying stress, heat, ultraviolet rays or the like. Furthermore, by forming the solder resists 127 in each of which openings are formed at positions corresponding to electrodes as shown in FIG. 22B, as first and second dielectric layers, workability in mounting and surface mounting of semiconductor elements thereafter can be improved. In addition, since the boards with different external shapes are stuck together, addition is performed only to a portion in which multilayer wirings are necessary, and thus the volume of the whole board can be reduced. In this exemplary embodiment in which the boards to be stuck are different from each other in external shape and the numbers of the boards connected through the third dielectric layer are different between the front side and the back side of the third dielectric layer, when the supporting plate is attached to at least the board on one of the sides at each portion of sticking through the third dielectric layer, there are advantages of uniform heating and uniform pressing in connecting, and flatness after pressing. It is also possible to provide a partially highly-multilayered board by sticking a conventional board with the board with the supporting plate according to the present invention.

Furthermore, it is also possible to form a high-performance board by sticking to a board including the fifth dielectric layer as a substrate of inorganic material when functions such as an inductor L, a capacitor C, and resistor R are added to inside a wiring of the inorganic board. Additionally, due to this structure, an area is provided on the dielectric layer on which the dielectric layer with a smaller external shape is mounted. The area can effectively be utilized by mounting other semiconductor elements or the like on the area in accordance with purposes, and a high-density wiring board suitable for various purposes can be provided. It is also possible to obtain a board with the same shape as a board to which a counter bore is provided after pressing by providing area to one of the boards each with supporting plate to be stuck together.

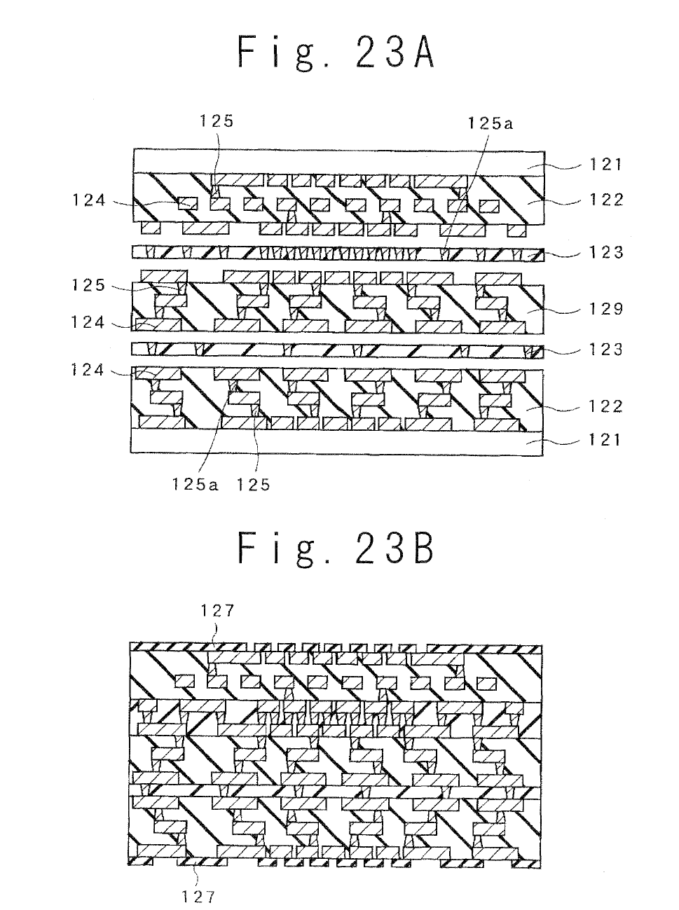

Next, a tenth exemplary embodiment of the present invention will be described. FIGS. 23A and 23B are cross-sectional views showing a wiring board for mounting semiconductor device according to the present exemplary embodiment. The wiring board for mounting semiconductor device according to the present exemplary embodiment is formed by combining the manufacturing method illustrated in FIGS. 19A and 19B with the manufacturing method illustrated in FIGS. 18A and 18B. As shown in FIG. 23A, the boards each with the supporting plate 121, in each of which the wiring 124 and the via 125 based on an arbitrary design are formed in the forth dielectric layer 122 mainly by a plating method, are used as upper end and lower end boards to be stuck together. The third dielectric layer 123 is formed on the uppermost layer at least one of the boards with the supporting plates 121 and a board without supporting plate to be put therebetween, of which substrate is a third dielectric layer 129. A via hole is formed to the dielectric layer 123, using laser, a drill, development by exposure, or other method, and the via 125a is formed by filling the via hole with conductive paste or solder paste using a printing method, a ink-jet method or other method. Alternatively, a via hole is formed in advance to the resin sheet 123 as the third dielectric layer using laser, a drill, development by exposure or other method, and the via 125a is formed by filling the via hole with conductive paste or solder paste using a printing method, an ink-jet method or other method. After that, the boards with the supporting plates 121 and the board without supporting plate are stuck together. As a result, sticking to conventional build-up board and printed board is possible with uniform heating and uniform load distribution by using the board with the supporting plate 121.

After that, as shown in FIG. 23B, the supporting plate 121 is removed by etching or by applying stress, heat, ultraviolet rays or the like. Furthermore, by forming the solder resists 127 in each of which openings are formed at positions corresponding to electrodes as shown in FIG. 23B, as first and second dielectric layers, workability in mounting and surface mounting of semiconductor elements thereafter can be improved. A highly-multilayered board can be formed by the pressing using a plurality of third dielectric layers 123 each having the via 125a filled with conductive paste or solder paste. It is preferable that the third dielectric layer 129 put between the boards on the front and back sides is different from the third dielectric layer 123 having the via 125a filled with conductive paste or solder paste in resin components, or the content of glass cloth, silica filler or aramid nonwoven fabric. As a result, it is possible to further improve the structural reliability of the board in the state after pressing shown in FIG. 23B.

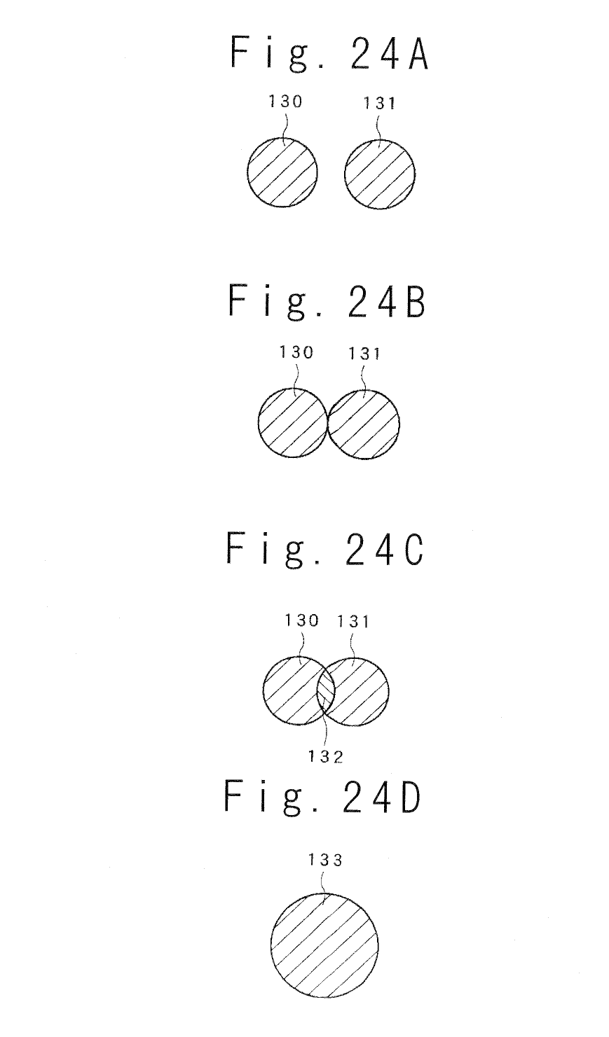

Here, FIGS. 24A to 24D show structures of powder particles in conductive paste or solder paste obtained by the manufacturing method of a wiring board for mounting semiconductor device according to the present invention. The conductive paste or solder paste used here is characterized in that it contains one or more kinds of powder particles with one or more kinds of alloys as a parent phase from the group of tin-bismuth binary alloy, tin-indium binary alloy, tin-zinc binary alloy, tin-silver binary alloy, tin-copper binary alloy, tin-gold binary alloy, tin-antimony binary alloy, and tin-nickel binary alloy. The kind of metal for the conductive paste or solder paste is selected based on the temperature at pressing below the heat resistant temperature of resin contained in the boards. The case that these binary alloys are used as the parent phase is, even when chemical elements added in a very small quantity and chemical elements irremovable in the manufacturing process of the particles are included, included in the scope of claims of the present invention.

Furthermore, required heat resistance cannot be satisfied in some cases when all these solder pastes are metals with low melting points. It is possible to improve the reliability in connection of the via by mixing one or more kinds of powders from the group of tin, bismuth, indium, copper, silver, zinc, gold, nickel, antimony, copper coated with silver and so forth, zinc coated with silver, organic filler coated with silver, and organic filler coated with tin, into the solder paste.

These powder particles in the conductive paste or solder paste are in a state of separation from each other like a powder particle A130 and a powder particle B131 as shown in FIG. 24A before pressing. The powder particle A130 and the powder particle B131 do not need to have the same composition. By applying a load and temperature in the pressing, the powder particle A130 and the powder particle B130 can come in contact with each other as shown in FIG. 24B.

Also in this state, structural strength inside the via can be maintained by providing paste binder with strength. When metal powders with melting temperatures below the temperature at the pressing are partially included, as shown in FIG. 24C, the metal powders melt to form a metal joining layer 132 between the adjacent powder particles as a result of elemental diffusion, and thus reliabilities are improved in electrical and structural functions. When all the metal powders in the via have melting temperatures below the temperature at the pressing, the powder particle A130 and the powder particle B131 melt into each other to form a bulk 133 as shown in FIG. 24D, and thus reliabilities are further improved in electrical and structural junctions. At this time, wettability between the powders differs depend on the activity of binder, solvent, flux or the like. In the case of poor wettability, metal joining partly occurs at the interface between the metal particles due to elemental diffusion.

In addition, metal joining due to elemental diffusion partly occurs at the interface between the metal particles also when the filling ratio of the powder particles inside the via is low or when the force of pressing is weak. When all the metal powders in the paste have melting temperatures above the temperature at the pressing, the metal powders do not melt but the adjacent metal particles can be metal-joined in the interface due to elementary diffusion to be the state of FIG. 24C. Even when the activities of binder and flux are low, an oxide film can be destructed by the pressing forces between the powders and between the powder and the electrode due to the pressing, and elemental diffusion can be enhanced. In this way, via connection with high reliability is possible due to metal components and binder and flux components included in the paste and pressing condition.

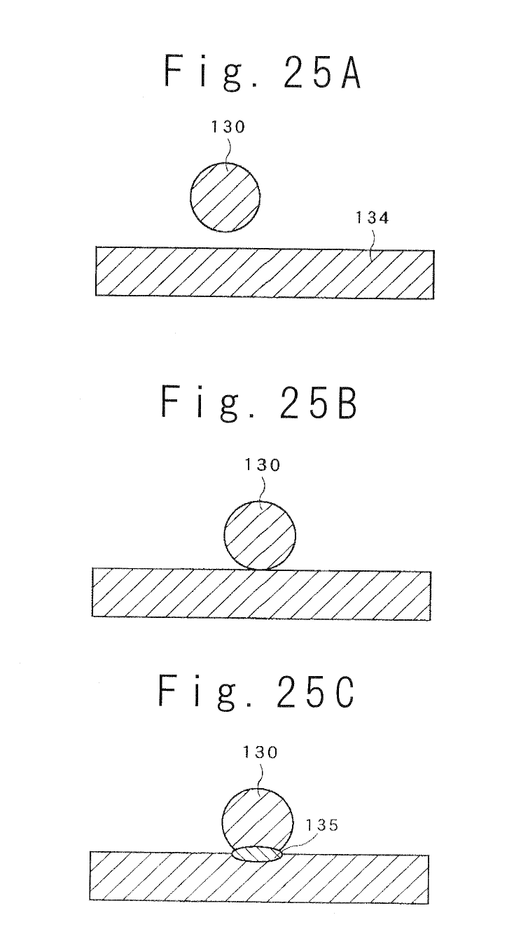

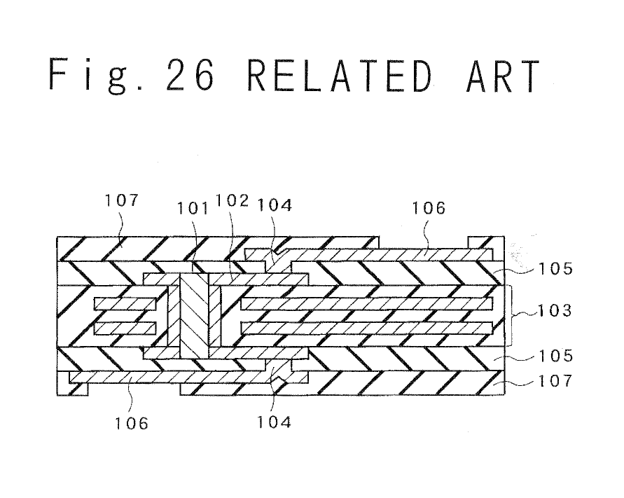

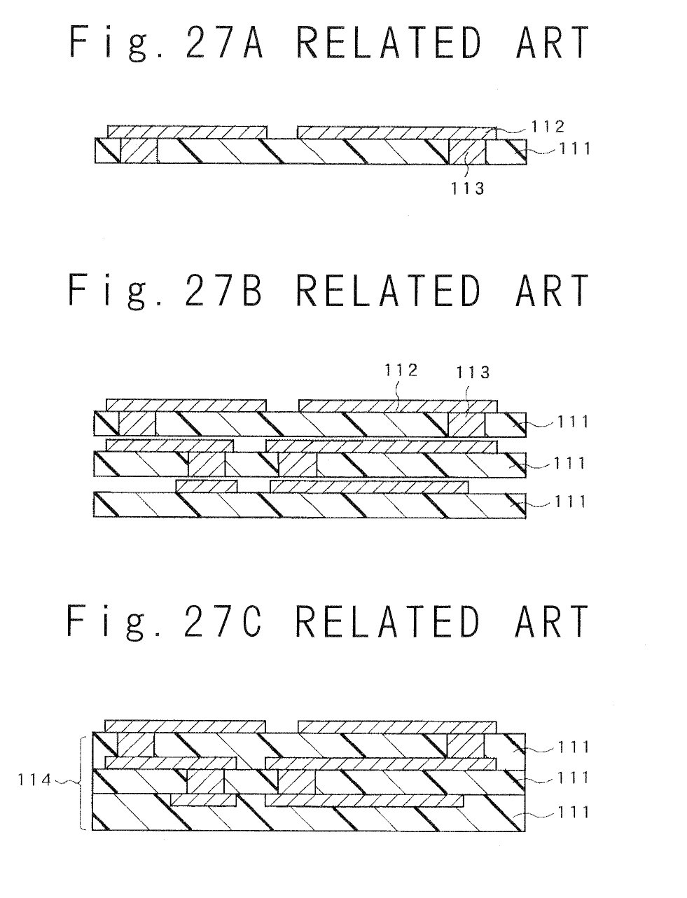

FIGS. 25A to 25C show structural states of a powder particle coming into contact with the electrode wiring layer to be stuck. Before pressing, the powder particle A130 and the electrode wiring 134 are separated from each other as shown in FIG. 25A. The powder particle A130 and the electrode wiring 134 can come into contact with each other as shown in FIG. 25B due to the pressing. Also in this state, structural strength inside the via can be maintained by providing paste binder with strength. When metal powders with melting temperatures below the temperature at the pressing are partially included, as shown in FIG. 25C, the metal powder melt to form a metal joining layer 135 between the metal powder and the electrode as a result of elemental diffusion, and thus reliabilities are improved in electrical and structural junctions. The via filled with conductive paste or solder paste also serves to remove an oxide film formed at the surface of the wiring layer of the board. The thickness of the intermetallic compound layer such as Cu—Sn, Sn—An, Au—Zn or Cu—Zn formed between the powder particle and the electrode is different depending on the activities of the binder and the flux used for the paste. Even when the activities of binder and flux are low, the oxide film can be destructed by the pressing forces between the powders and between the powder and the electrode during the pressing. In this way, via connection with high reliability is possible due to metal components and binder and flux components included in the paste and pressing condition.

As described in detail above, the present invention makes it possible to obtain a new wiring board for mounting semiconductor device, which is effective for an increase in terminals and finer pitch of terminal intervals due to an improvement in integration, performance or multi-function of semiconductor devices, can mount semiconductor devices especially on both sides of the board at a high density and high accuracy, and further more, is excellent in reliability as well.

1-42. (canceled)

43. A wiring board for mounting semiconductor device, comprising:
a dielectric film;
wirings formed in said dielectric film;
a plurality of electrode pads provided at front and back surfaces of said dielectric film with surfaces of the plurality of electrode pads exposed and at least portions of lateral sides of said plurality of electrode pads buried into said dielectric film; and
vias connecting said wirings and said plurality of electrode pads,
wherein at least one via connecting each other said wirings formed in said dielectric film includes second material different from first material forming said vias connecting said wiring and said plurality of electrode pads.

44. The wiring board for mounting semiconductor device according to claim 43, wherein said dielectric film includes:
a first dielectric layer positioned at a front surface of the wiring board;
a second dielectric layer positioned at a back surface of the wiring board; and
one or more third dielectric layers positioned inside the wiring board,
a plurality of wirings buried at both surfaces of said third dielectric layers and vias connecting said plurality of wirings are provided to said third dielectric layers,
said plurality of electrode pads are provided with surfaces thereof being exposed at a surface of said first dielectric layer at a front surface side of the wiring board and at a surface of said second dielectric layer at a back surface side of the wiring board,
at least said portions of said lateral sides of said plurality of electrode pads are buried in said first dielectric layer or said second dielectric layer, and
at least one via connecting said plurality of wirings buried in said both surfaces of said third dielectric layers includes second material different from first material forming vias formed in said first dielectric layer and said second dielectric layer.

45. The wiring board for mounting semiconductor device according to claim 44, wherein said vias connecting said plurality of wirings buried in said both surfaces of said third dielectric layers includes:
a via which connects wirings most remote from said first dielectric layer and said second dielectric layer and includes second material different from first material forming the rest vias.

46. The wiring board for mounting semiconductor device according to claim 43, wherein said second material is conductive paste or solder paste.

47. The wiring board for mounting semiconductor device according to claim 43, wherein said second material is conductive paste or solder paste including two or more kinds of powder particles.

48. The wiring board for mounting semiconductor device according to claim 43, wherein said second material includes at least one kind of powder particles of tin, bismuth, indium, copper, silver, zinc, gold, nickel, antimony, copper coated with silver, zinc coated with silver, organic filler coated with silver, and organic filler coated with tin in conductive paste or solder paste.

49. The wiring board for mounting semiconductor device according to claim 43, wherein said second material includes at least one kind of powder particles including as a parent phase at least one kind of alloy selected from a group of tin-bismuth binary alloy, tin-indium binary alloy, tin-zinc binary alloy, tin-silver binary alloy, tin-copper binary alloy, tin-gold binary alloy, tin-antimony binary alloy, and tin-nickel binary alloy in conductive paste or solder paste.

50. The wiring board for mounting semiconductor device according to claim 43, wherein an inside portion of said via formed of said second material includes a portion of a shape of a bulk, and
said bulk includes at least one kind of element selected from a group of tin, bismuth, indium, copper, silver, zinc, gold and nickel.

51. The wiring board for mounting semiconductor device according to claim 43, wherein said second material is conductive paste or solder paste including metal powder particles, and
said metal powder particles form a metal joining layer in said via formed of said second material.

52. The wiring board for mounting semiconductor device according to claim 43, wherein said first material includes at least one kind of metal selected from a group of copper, nickel and gold.

53. The wiring board for mounting semiconductor device according to claim 44, wherein at least said first dielectric layer and said second dielectric layer among said first dielectric layer, said second dielectric layer and said third dielectric layer are formed of different materials.

54. The wiring board for mounting semiconductor device according to claim 44, further comprising:
at least one layer of forth dielectric layer including a wiring and a via, which is provided at least one of positions between said first dielectric layer and said third dielectric layer and between said second dielectric layer and said third dielectric layer.

55. The wiring board for mounting semiconductor device according to claim 54, wherein an external shape of at least one dielectric layer of a dielectric layer at an upper side of said third dielectric layer and a dielectric layer at a lower side of said third dielectric layer is different from an external shape of said third dielectric layer.

56. The wiring board for mounting semiconductor device according to claim 54, wherein an external shape of one dielectric layer of a dielectric layer at an upper side of said third dielectric layer and a dielectric layer at a lower side of said third dielectric layer is same as an external shape of said third dielectric layer, and
an external shape of another dielectric layer of said dielectric layer at said upper side of said third dielectric layer and said dielectric layer at said lower side of said third dielectric layer is smaller than said external shape of said third dielectric layer.

57. The wiring board for mounting semiconductor device according to claim 56, further comprising:
at least one dielectric layer other than said another dielectric layer on a surface of said third dielectric layer, and
wherein an external shape of said at least one dielectric layer other than said another dielectric layer is smaller than said external shape of said third dielectric layer, and
said surface of said third dielectric layer contacts with said another dielectric layer.

58. The wiring board for mounting semiconductor device according to claim 54, wherein at least one dielectric layer of said first, second and forth dielectric layers includes a wiring layer of inorganic material, and
said third dielectric layer is formed of organic material.

59. The wiring board for mounting semiconductor device according to claim 44, wherein said third dielectric layer includes epoxy resin.

60. The wiring board for mounting semiconductor device according to claim 44, wherein said third dielectric layer includes polyimide resin.

61. The wiring board for mounting semiconductor device according to claim 44, wherein said third dielectric layer includes acrylic resin.

62. The wiring board for mounting semiconductor device according to claim 44, wherein said third dielectric layer includes glass cloth.

63. The wiring board for mounting semiconductor device according to claim 44, wherein said third dielectric layer includes silica filler.

64. The wiring board for mounting semiconductor device according to claim 44, wherein said third dielectric layer includes aramid nonwoven fabric.

65. The wiring board for mounting semiconductor device according to claim 44, wherein said third dielectric layer includes thermosetting resin.

66. The wiring board for mounting semiconductor device according to claim 44, wherein said third dielectric layer includes thermoplastic resin.

67. The wiring board for mounting semiconductor device according to claim 44, wherein said third dielectric layer includes photosensitive resin.

68. The wiring board for mounting semiconductor device according to claim 43, an exposed surface of at least one of said plurality of electrode pads is arranged at a same level of said front surface or said back surface of said dielectric film.

69. The wiring board for mounting semiconductor device according to claim 43, an exposed surface of at least one of said plurality of electrode pads is depressed from said front surface or said back surface of said dielectric film.

70. The wiring board for mounting semiconductor device according to claim 43, an exposed surface of at least one of said plurality of electrode pads protrudes from said front surface or said back surface of said dielectric film.

71. The wiring board for mounting semiconductor device according to claim 43, a surface of at least one of said plurality of electrode pads is partially covered by said dielectric film.

72. The wiring board for mounting semiconductor device according to claim 43, a supporting body is provided on at least a portion of said front surface or said back surface of said dielectric film.

73. The wiring board for mounting semiconductor device according to claim 43, a solder resist layer is provided on at least one of said front and back surfaces of said dielectric film.

74. A wiring board assembly comprising:
a wiring board; and
semiconductor elements mounted on said wiring board,
wherein said wiring board includes:
a dielectric film;
wirings formed in said dielectric film;
a plurality of electrode pads provided at front and back surfaces of said dielectric film with surfaces of the plurality of electrode pads exposed and at least portions of lateral sides of said plurality of electrode pads buried into said dielectric film; and
vias connecting said wirings and said plurality of electrode pads,
wherein at least one via connecting each other said wirings formed in said dielectric film includes second material different from first material forming said vias connecting said wiring and said plurality of electrode pads.
